(19) United States
(12) Patent Application Publication
(10) Pub. No.: US 2026/0172055 A1
(43) Pub. Date: Jun. 18, 2026

(54) DECODING BASED ON DATA RELIABILITY

(71) Applicant: QUALCOMM Incorporated, San Diego, CA (US)

(72) Inventors: Reza BARAZIDEH, La Jolla, CA (US); Alberto RICO ALVARINO, San Diego, CA (US); Zisis Iason SKORDILIS, San Diego, CA (US); Liangping MA, San Diego, CA (US); Vivek RAJENDRAN, San Diego, CA (US); Duminda DEWASURENDRA, San Diego, CA (US); Guillaume Konrad SAUTIERE, Amsterdam (NL)

(21) Appl. No.: 19/123,641

(22) PCT Filed: Sep. 26, 2023
(86) PCT No.: PCT/US2023/075083

§ 371 Date: Apr. 23, 2025

(30) Foreign Application Priority Data
Dec. 2, 2022 (GR) 20220101003

(51) Int. Cl. H03M 13/00; G06N 3/04; H03M 13/37

(52) U.S. Cl. CPC H03M 13/615; G06N 3/04; H03M 13/37

(57) ABSTRACT

A device includes one or more processors configured to obtain first bits representing first encoded time-series data and to obtain a first indicator of reliability of the first bits. The one or more processors are also configured to process an input using one or more trained models to generate decoded output. The input is based at least in part on the first bits and the first indicator, and the decoded output represents decoded time-series data.

### I. FIELD

The present disclosure is generally related to decoding encoded data based on data reliability.

### II. DESCRIPTION OF RELATED ART

Advances in technology have resulted in smaller and more powerful computing devices as well as an increase in the availability of and consumption of media. For example, there currently exist a variety of portable personal computing devices, including wireless telephones such as mobile and smart phones, tablets and laptop computers that are small, lightweight, and easily carried by users and that enable generation of media content and consumption of media content nearly anywhere.

An increase in data communications over wired and wireless networks has accompanied the increased availability and use of such computing devices. Communication of large amounts of data (such as may be associated with streaming of high-quality media content) in a timely, efficient, and reliable manner is challenging for a variety of reasons. Data compression techniques and error detection and error correction techniques have been developed to alleviate some of these challenges. To some extent, error detection/correction techniques are at odds with data compression techniques since an object of data compression is to reduce an amount of data to be transmitted (often by removing redundant information) whereas error detection/correction techniques generally add redundant information to a data stream.

### III. SUMMARY

According to a particular aspect, a device includes one or more processors configured to obtain first bits representing first encoded time-series data and to obtain a first indicator of reliability of the first bits. The one or more processors are also configured to process an input using one or more trained models to generate decoded output. The input is based at least in part on the first bits and the first indicator, and the decoded output represents decoded time-series data.

According to a particular aspect, a method includes obtaining, by one or more processors, first bits representing first encoded time-series data and obtaining, by the one or more processors, a first indicator of reliability of the first bits. The method also includes processing, by the one or more processors, an input using one or more trained models to generate decoded output. The input is based at least in part on the first bits and the first indicator, and the decoded output represents decoded time-series data.

According to a particular aspect, a non-transitory computer-readable medium stores instructions that, when executed by one or more processors, cause the one or more processors to obtain first bits representing first encoded time-series data and obtain a first indicator of reliability of the first bits. The instructions are further executable by one or more processors to process an input using one or more trained models to generate decoded output. The input is based at least in part on the first bits and the first indicator, and the decoded output represents decoded time-series data.

According to a particular aspect, an apparatus includes means for obtaining first bits representing first encoded time-series data and means for obtaining a first indicator of reliability of the first bits. The apparatus also includes means for processing an input using one or more trained models to generate decoded output. The input is based at least in pan on the first bits and the first indicator, and the decoded output represents decoded time-series data.

Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a block diagram of a particular illustrative aspect of a system operable to decode encoded data based on data reliability, in accordance with some examples of the present disclosure.

FIG. 2 is a diagram of particular aspects of the system of FIG. 1, in accordance with some examples of the present disclosure.

FIG. 3A is a diagram of particular aspects of the system of FIG. 1, in accordance with some examples of the present disclosure.

FIG. 3B is a diagram of particular aspects of the system of FIG. 1, in accordance with some examples of the present disclosure.

FIG. 4 is a diagram of particular aspects of the system of FIG. 1, in accordance with some examples of the present disclosure.

FIG. 5 is a diagram of particular aspects of the system of FIG. 1, in accordance with some examples of the present disclosure.

FIG. 6 is a diagram of particular aspects of the system of FIG. 1, in accordance with some examples of the present disclosure.

FIG. 7 is a diagram of particular aspects of the system of FIG. 1, in accordance with some examples of the present disclosure.

FIG. 8 is a diagram of particular aspects of the system of FIG. 1, in accordance with some examples of the present disclosure.

FIG. 9 is a diagram of particular aspects of the system of FIG. 1, in accordance with some examples of the present disclosure.

FIG. 10 is a diagram of particular aspects of the system of FIG. 1, in accordance with some examples of the present disclosure.

FIG. 11 is a diagram of particular aspects of the system of FIG. 1, in accordance with some examples of the present disclosure.

FIG. 12 illustrates an example of an integrated circuit operable to decode encoded data based on data reliability, in accordance with some examples of the present disclosure.

FIG. 13 is a diagram of a mobile device operable to decode encoded data based on data reliability, in accordance with some examples of the present disclosure.

FIG. 14 is a diagram of a headset operable to decode encoded data based on data reliability, in accordance with some examples of the present disclosure.

FIG. 15 is a diagram of a wearable electronic device operable decode encoded data based on data reliability, in accordance with some examples of the present disclosure.

FIG. 16 is a diagram of a mixed reality or augmented reality glasses device operable to decode encoded data based on data reliability, in accordance with some examples of the present disclosure.

FIG. 17 is a diagram of earbuds operable to decode encoded data based on data reliability, in accordance with some examples of the present disclosure.

FIG. 18 is a diagram of a voice-controlled speaker system operable to decode encoded data based on data reliability, in accordance with some examples of the present disclosure.

FIG. 19 is a diagram of a camera operable to decode encoded data based on data reliability, in accordance with some examples of the present disclosure.

FIG. 20 is a diagram of a headset, such as a virtual reality, mixed reality, or augmented reality headset, operable to decode encoded data based on data reliability, in accordance with some examples of the present disclosure.

FIG. 21 is a diagram of a first example of a vehicle operable to decode encoded data based on data reliability, in accordance with some examples of the present disclosure.

FIG. 22 is a diagram of a second example of a vehicle operable to decode encoded data based on data reliability, in accordance with some examples of the present disclosure.

FIG. 23 is a diagram of a particular implementation of a method of decoding encoded data based on data reliability that may be performed by the device of FIG. 1, in accordance with some examples of the present disclosure.

FIG. 24 is a block diagram of a particular illustrative example of a device that is operable to decode encoded data based on data reliability, in accordance with some examples of the present disclosure.

### V. DETAILED DESCRIPTION

Aspects disclosed herein use data reliability information during decoding of encoded data. For example, a decoder includes one or more machine-learning models that are trained to decode the encoded data. In this example, the machine-learning model(s) are configured to take as input a representation of the encoded data and reliability information associated with the representation of the encoded data. In some implementations, the input to the machine-learning model(s) may also include other information.

In a particular aspect, transmission of encoded data over a communication channel can introduce errors. Generally, such errors correspond to flipping of just a few bits of the data. Error correction code can correct some such errors, but occasionally, a packet may be received that includes more errors than a correction limit of the error correction code, resulting in an uncorrectable packet. Conventional techniques to deal with uncorrectable packets include requesting retransmission of such packets or replacing an uncorrectable packet with a previously received packet. In contrast, the disclosed techniques provide data representing the uncorrectable packet and reliability information to the decoder, and the decoder generates decoded output that represents an estimate of a decoded version of the encoded data.

Under typical transmission conditions, most of the bits of an uncorrectable packet are correct. For example, it is generally more likely that the number of erroneous bits in the uncorrectable packet exceeds the correction limit of the error correction code by a small amount, rather than by a large amount. Aspects disclosed herein take advantage of this expectation that an uncorrectable packet will include some correct information by training a machine-learning based decoder to account for data reliability during a decoding process.

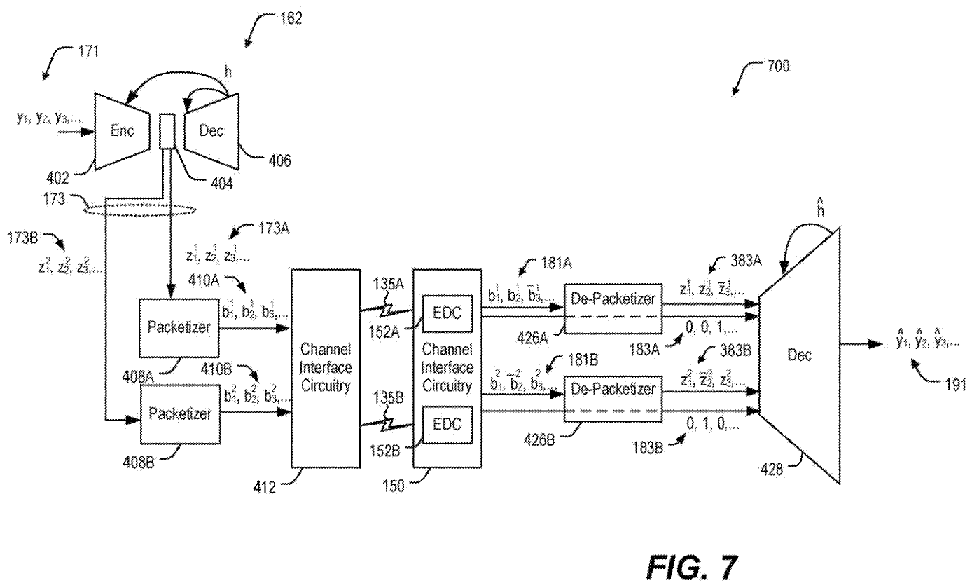

Particular aspects of the present disclosure are described below with reference to the drawings. In the description, common features are designated by common reference numbers. In some drawings, multiple instances of a particular type of feature are used. Although these features are physically and/or logically distinct, the same reference number is used for each, and the different instances are distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 7, multiple packetizers are illustrated and associated with reference numbers 408A and 408B. When referring to a particular one of these packetizers, such as the packetizer 408A, the distinguishing letter “A” is used. However, when referring to any arbitrary one of these packetizers or to these packetizers as a group, the reference number 408 is used without a distinguishing letter.

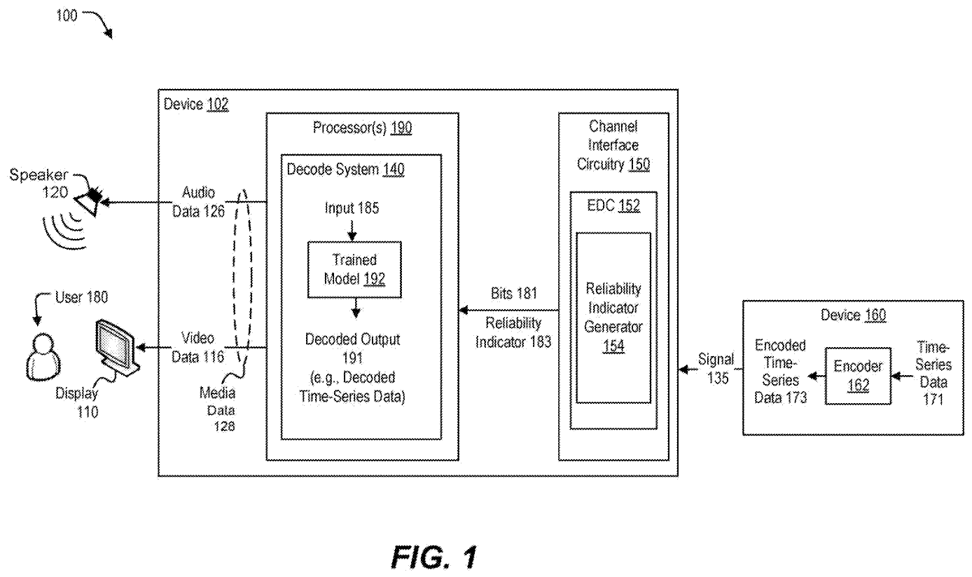

As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. To illustrate. FIG. 1 depicts a device 102 including one or more processors (“processor(s)” 190 of FIG. 1), which indicates that in some implementations the device 102 includes a single processor 190 and in other implementations the device 102 includes multiple processors 190. For ease of reference herein, such features are generally introduced as “one or more” features and are subsequently referred to in the singular or optional plural (as indicated by “(s)” in the name of the feature) unless aspects related to multiple of the features are being described.

As used herein, the terms “comprise,” “comprises.” and “comprising” may be used interchangeably with “include,” “includes,” or “including.” Additionally, the term “wherein” may be used interchangeably with “where.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, “coupled” may include “communicatively coupled.” “electrically coupled,” or “physically coupled.” and may also (or alternatively) include any combinations thereof. Two devices (or components) may be coupled (e.g., communicatively coupled, electrically coupled, or physically coupled) directly or indirectly via one or more other devices, components, wires, buses, networks (e.g., a wired network, a wireless network, or a combination thereof), etc. Two devices (or components) that are electrically coupled may be included in the same device or in different devices and may be connected via electronics, one or more connectors, or inductive coupling, as illustrative, non-limiting examples. In some implementations, two devices (or components) that are communicatively coupled, such as in electrical communication, may send and receive signals (e.g., digital signals or analog signals) directly or indirectly, via one or more wires, buses, networks, etc. As used herein, “directly coupled” may include two devices that are coupled (e.g., communicatively coupled, electrically coupled, or physically coupled) without intervening components.

In the present disclosure, terms such as “determining,” “calculating,” “estimating,” “shifting,” “adjusting,” etc. may be used to describe how one or more operations are performed. It should be noted that such terms are not to be construed as limiting and other techniques may be utilized to perform similar operations. Additionally, as referred to herein. “generating,” “calculating,” “estimating,” “using.” “selecting,” “accessing.” and “determining” may be used interchangeably. For example, “generating,” “calculating,” “estimating,” or “determining” a parameter (or a signal) may refer to actively generating, estimating, calculating, or determining the parameter (or the signal) or may refer to using, selecting, or accessing the parameter (or signal) that is already generated, such as by another component or device.

As used herein, the term “machine learning” should be understood to have any of its usual and customary meanings within the fields of computers science and data science, such meanings including, for example, processes or techniques by which one or more computers can learn to perform some operation or function without being explicitly programmed to do so. As a typical example, machine learning can be used to enable one or more computers to analyze data to identify patterns in data and generate a result based on the analysis. For certain types of machine learning, the results that are generated include a data model (also referred to as a “machine-learning model” or simply a “model”). Typically, a model is generated using a first data set to facilitate analysis of a second data set. For example, a first portion of a large body of data may be used to generate a model that can be used to analyze the remaining portion of the large body of data. As another example, a set of historical data can be used to generate a model that can be used to analyze future data. Examples of machine-learning models include, without limitation, perceptrons, neural networks, support vector machines, regression models, decision trees. Bayesian models, Boltzmann machines, adaptive neuro-fuzzy inference systems, as well as combinations, ensembles and variants of these and other types of models. Variants of neural networks include, for example and without limitation, prototypical networks, autoencoders, transformers, self-attention networks, convolutional neural networks, deep neural networks, deep belief networks, etc. Variants of decision trees include, for example and without limitation, random forests, boosted decision trees, etc.

Since machine-learning models am generated by computer(s) based on input data, machine-learning models can be discussed in terms of at least two distinct time windows—a creation/training phase and a runtime phase. During the creation/training phase, a model is created, trained, adapted, validated, or otherwise configured by the computer based on the input data (which in the creation/training phase, is generally referred to as “training data”). Note that the trained model corresponds to software that has been generated and/or refined during the creation/training phase to perform particular operations, such as classification, prediction, encoding, or other data analysis or data synthesis operations. During the runtime phase (or “inference” phase), the model is used to analyze input data to generate model output. The content of the model output depends on the type of model. For example, a model can be trained to perform classification tasks or regression tasks, as non-limiting examples. In some implementations, a model may be continuously, periodically, or occasionally updated, in which case training time and runtime may be interleaved or one version of the model can be used for inference while a copy is updated, after which the updated copy may be deployed for inference.

FIG. 1 is a block diagram of a particular illustrative aspect of a system 100 operable to decode encoded data based on data reliability, in accordance with some examples of the present disclosure. In FIG. 1, the system 100 includes a device 102 and a device 160 that are configured to communicate via one or more signals (e.g., signal 135). For ease of illustration. FIG. 1 depicts the device 160 sending the signal 135 to the device 102; however, in other implementations, data exchange in the system 100 may be two-way. For example, the device 102 may also, or alternatively, send signals to the device 160. Further, although two devices are illustrated in FIG. 1, in other implementations, more than two devices communicate using the disclosed techniques.

In FIG. 1, the device 160 includes an encoder 162 that is configured to encode time-series data 171 to generate encoded time-series data 173. The device 160 is configured to transmit, via the signal 135, a representation of the encoded time-series data 173 to the device 102. The signal 135 may be transmitted over a wired medium, a wireless medium, or both. For ease of reference, a medium of the signal 135 is referred to herein as simply a “communication channel” or a “channel.”

The device 102 includes channel interface circuitry 150 and one or more processors 190. The channel interface circuitry 150 is configured to generate bits 181 based on the signal 135. For example, the signal 135 may be modulated to represent a plurality of symbols, and the channel interface circuitry 150 may map each symbol received via the signal 135 to corresponding bits of the bits 181.

In the example illustrated in FIG. 1, the channel interface circuitry 150 includes error detection and/or correction circuitry (EDC) 152. The EDC 152 includes error detection circuitry, error correction circuitry, or both, configured to process the signal 135 to determine bits of the encoded time-series data 173 and also redundancy information (e.g., parity bits) that accompany the bits of the encoded time-series data 173, any of which may be erroneous due to one or more bit errors, such as due to cosmic rays, signal interference in the communication channel, etc. A reliability indicator generator 154 is configured to generate a reliability indicator 183 in conjunction with decoding (or attempting to decode) a set of received bits. In the event that the number of erroneous bits does not exceed a correction capacity of the EDC 152, the EDC 152 corrects the erroneous bits, which are output as the bits 181. Otherwise, the erroneous decoded bits (e.g., including bit errors) are output as the bits 181. In FIG. 1, the EDC 152 includes the reliability indicator generator 154 which is configured to generate a reliability indicator 183 associated with the bits 181. Although FIG. 1 illustrates the reliability indicator generator 154 as a component of the EDC 152, in other examples, the reliability indicator generator 154 is included in the one or more processor(s) 190 or in another component of the device 102.

In some implementations, the bits 181 correspond to a set of bits representing a packet of data, and the reliability indicator 183 includes a packet-level reliability indicator. For example, the reliability indicator 183 associated with a packet may indicate whether the bits 181 of the packet include one or more uncorrectable errors (e.g., errors that could not be corrected by the EDC 152). As another example, the reliability indicator 183 associated with a packet may include a value of a quality metric, such as an estimated signal-to-noise ratio (SNR) associated with the packet, an average log-likelihood ratio (LLR) absolute value associated with processing of the packet by the EDC 152, an estimated bit error rate (BER) associated with the packet, an estimated symbol error rate associated with the packet, etc.

In some implementations, the reliability indicator 183 includes a bit-level indicator. For example, in some such implementations, the reliability indicator 183 includes LLRs of the bits 181 generated by the EDC 152. In still other implementations, the reliability indicator 183 includes a channel-level indicator. For example, the reliability indicator 183 includes information indicating channel quality (e.g., quality associated with transmission of multiple packets), such as a block error rate (BLER). In some implementations, the reliability indicator 183 includes two or more of a bit-level indicator, a packet-level indicator, and a channel-level indicator.

The processor(s) 190 are configured to perform a variety of operations to generate output data that reproduces or approximates the time-series data 171. In some implementations, the processor(s) 190 include or correspond to general-purpose processors configured to execute instructions from a memory, such as central processing units (CPUs), graphics processing units (GPUs), digital signal processors (DSPs), or one or more neural processing units (NPUs). In some implementations, the processor(s) 190 include or correspond to special purpose circuitry that is configured to perform particular operations, such as field-programmable gate array (FPGA) devices, application-specific integrated circuit (ASICs), controllers, and certain other hardware or firmware devices. In some implementations, the processor(s) 190 include or correspond to a combination of general-purpose and special purpose circuitry.

In some implementations, the time-series data 171 represents media content, and the processor(s) 190 are configured to generate media data 128 that reproduces or approximates the media content of the time-series data 171. To illustrate, at least a portion of the time-series data 171 may represent audio content, and the processor(s) 190 are configured to generate audio data 126 that reproduces or approximates the audio content of the time-series data 171. As another illustrative example, the time-series data 171 may represent video content, and the processor(s) 190 are configured to generate video data 116 that reproduces or approximates the video content of the time-series data 171. In other examples, the media data 128 include game data, extended reality data (e.g., augmented reality, mixed reality, or virtual reality data), or other forms of media represented by the time-series data 171.

The device 102 may be coupled to or include one or more output devices that are configured to present the media content of the media data 128 to a user 180. For example, in FIG. 1, the device 102 is coupled to one or more speakers (e.g., speaker 120) that are configured to generate sound based on the audio data 126. As another example, the device 102 is coupled to one or more displays (e.g., display 110) that are configured to generate a sequence of images (e.g., video) based on the video data 116.

In FIG. 1, the processor(s) 190 include a decode system 140, which includes one or more trained models, such as a representative trained model 192. The trained model 192 is configured to receive input 185 that is based on the bits 181 and based on the reliability indicator 183, and to generate decoded output 191 based on the input 185. In a particular example, the decoded output 191 corresponds to decoded time-series data representing the time-series data 171. One benefit of the input 185 being based on or including both the bits 181 and the reliability indicator 183 associated with the bits 181 is that inclusion of the reliability indicator 183 enables the trained model 192 to take into account errors introduced by the channel and to be more resilient to such errors.

To illustrate, in a particular implementation, the reliability indicator 183 includes a single binary value per packet, such as a value of 0 (indicating that the bits 181 of the packet include no errors) and a value of 1 (indicating that the bits 181 of the packet include at least one error). In this implementation, the binary value of the reliability indicator 183 may be provided as input to the trained model 192 along with values based on the bits 181. In this implementation, particular values of the input 185 that are based on the bits 181 result in first values of the decoded output 191 if the input 185 includes a 0 value for the reliability indicator 183 and result in different values of the decoded output 191 if the input 185 includes a I value for the reliability indicator 183. Stated another way, decoding of the bits 181 is affected by whether the reliability indicator 183 indicates that the bits 181 have errors.

In another particular implementation, the reliability indicator 183 includes one or more values per packet, where the value(s) indicate a quality metric associated with the packet. For example, for a packet with one or more uncorrectable errors, the quality metric may indicate an estimated signal-to-noise ratio, an average log likelihood ratio (LLR) absolute value, an estimated bit error rate (BER), an estimated symbol error rate, or a combination thereof. In this example, for a packet with no uncorrectable errors, the value of the quality metric may have a null value, a default value, or another value indicating that the packet has no uncorrectable errors. In this implementation, particular values of the input 185 that are based on the bits 181 result in different values of the decoded output 191 depending on the value of the quality metric of the reliability indicator 183.

In each of the implementations above, the reliability indicator 183 provides information that the trained model 192 uses to decode the portion of the input 185 that is based on the bits 181, thereby enabling the trained model 192 to generate an estimated decoded output 191 even when the input 185 is based on a packet with one or more uncorrectable errors.

In a particular implementation, the encoder 162 includes, corresponds to, or is included within, an autoencoder. In this implementation, the encoded time-series data 173 include a vector of values from a bottleneck layer of the autoencoder (also referred to herein as “latent vector values”). In this implementation, the latent vector values are packetized (which may include quantizing and/or error correction encoding the values) and transmitted as a series of symbols via the signal 135.

The channel interface circuitry 150 determines one or more bits 181 represented by each symbol. In some instances, the EDC 152 determines that one or more of the bits 181 were flipped in the channel and flips such bits 181 to their original values. In some circumstances, the EDC 152 may be able to determine that the bits 181 of a particular packet are not correct but may not be able to determine which of the bits 181 to flip to correct the packet. If the EDC 152 is able to correct all of the bits 181 of a packet, the channel interface circuitry 150 outputs the corrected bits 181 and a reliability indicator 183 indicating that the bits 181 are reliable (e.g., that the packet does not include any uncorrectable error). If the EDC 152 is not able to correct all of the bits 181 of a packet, the channel interface circuitry 150 outputs the bits 181 with whatever corrections can be made (if any) and a reliability indicator 183 indicating that the bits 181 are not reliable (e.g., that the packet includes one or more uncorrectable errors). As explained above, in some implementations, the reliability indicator 183 may also, or alternatively, include a value of a quality metric.

The bits 181 or data based on the bits 181 are used as a first portion of the input 185 to the trained model 192. For example, in a particular implementation, the trained model 192 includes one or more layers that are arranged (and trained) to map values of the bits to latent vector values (e.g., estimates of the latent vector values of the encoder 162). In this example, the input 185 includes the bits 181. As another example, in a particular implementation, another operation, such as a codebook lookup, is performed based on the bits 181 to determine values of a vector, where the values of the vector are estimates of the latent vector values of the encoder 162. In this example, the values of the vector are included in the input 185. In either of these implementations, the input 185 also includes the reliability indicator 183 associated with the bits 181.

The trained model 192 generates the decoded output 191 based on the input 185. In a particular implementation, the trained model 192 is operable to generate reliable (e.g., based on one or more quantifiable metrics) estimates of the time-series data 171 when the input 185 is based on bits 181 without channel introduced errors and when the input 185 is based on bits 181 with some channel introduced errors. In some implementations, if a particular set of bits 181 includes too many channel introduced errors, the decode system 140 may drop the particular set of bits 181 and generate the input 185 based on bits from a prior packet. For example, after first bits 181 associated with a first packet have been processed by the channel interface circuitry 150 and provided to the processor(s) 190, the channel interface circuitry 150 may receive, via the signal 135, symbols corresponding to second bits 181 of a second packet. In this example, the channel interface circuitry 150 performs, based on the symbols representing the second packet, error detection operations, error correction operations, or both, to determine the second bits and to determine error statistics associated with the second bits. In this example, the channel interface circuitry 150 or the processor(s) 190 compare the error statistics associated with the second bits to a threshold. In response to determining that the error statistics associated with the second bits fail to satisfy the threshold, the decode system 140 causes the trained model 192 to process input 185 that is based on copies of the first bits 181 of the first packet and a second reliability indicator 183 associated with the second bits.

Although FIG. 1 illustrates one set of encoded time-series data 173 transmitted via one signal 135, in some implementations, the encoder 162 may be configured to encode the time-series data 171 to generate two or more sets of encoded time-series data 173, which may be transmitted via two or more signals 135. For example, when the tine-scries data 171 include audio data representing speech, some characteristics of audio data may be more important than others for producing intelligible audio data 126 at the device 102. In this example, the more important features of the audio data may be encoded to generate first encoded time-series data and the less important features of the audio data may be encoded to generate second encoded time-series data. In this example, the first encoded time-series data may be transmitted to the device 102 using a first error protection scheme, and the second encoded time-series data may be transmitted to the device 102 using a second error protection scheme, where the first error protection scheme provides greater protection than the second error protection scheme. In this example, the channel interface circuitry 150 generates bits 181 representing each of the first encoded time-series data and the second encoded time-series data and generates reliability indicators 183 for each. In a particular implementation of this example, the decode system 140 may include a single trained model that is configured and trained to receive input based on the bits representing the first encoded time-series data, the bits representing the second encoded time-series data and reliability indicators for each. In an alternative implementation, the decode system 140 may include a first trained model that is configured and trained to receive input based on first bits representing the first encoded time-series data the reliability indicator associated with the first bits, and the decode system 140 may further include a second trained model that is configured and trained to receive input based on second bits representing the second encoded time-series data the reliability indicator associated with the second bits. In this alternative implementation, the decode system 140 may further include a third trained model that is configured to receive output of the first trained model and the second trained model to generate the decoded output 191. Thus, the system 100 may use different levels of protection for different types of data or for data representing different aspects of the time-series data 171.

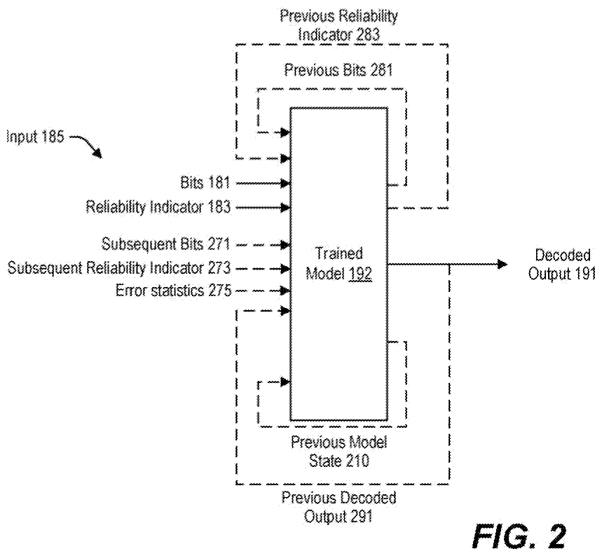

FIG. 2 is a diagram of particular aspects of the system of FIG. 1, in accordance with some examples of the present disclosure. In particular, FIG. 2 illustrates an example of various inputs (collectively the input 185) and outputs of the trained model 192.

In FIG. 2, the input 185 includes the bits 181 and the reliability indicator 183, as described with reference to FIG. 1. In some implementations, rather than the bits 181, the input 185 includes values determined based on the bits 181, such as values of a vector determined via a codebook lookup based on the bits 181.

FIG. 2 also illustrates a variety of optional components of the input 185. In some implementations, the input 185 includes additional data related to one or more previously processed sets of data. For example, the input 185 may optionally include previous bits 281 (e.g., bits associated with a prior packet of a time-series of packets), a previous reliability indicator 283 associated with the previous bits 281, or both.

Additionally, or alternatively, the input 185 may include previous decoded output 291, previous model state(s) 210, or both. The previous model state(s) 210 are a function of one or more prior inputs 185 to the trained model 192.

In the same or different implementations, the input 185 includes additional data related to packets that arm subsequent to the current packet in the time-series of packets. For example, when the bits 181 represent a packet with a time index t, the input 185 can also include data associated with one or more packets having time indices t+1, t+2, . . . t+n, (where n is an integer greater than 2). In such implementations, the additional data related to packets that are subsequent to the current packet in the time-series of packets may include, for example, subsequent bits 271 (e.g., bits corresponding to a subsequent packet), a subsequent reliability indicator 273 associated with the subsequent bits 271, or both.

In the same or different implementations, the input 185 includes additional data related to channel or multi-packet reliability information, such as error statistics 275. In this example, the error statistics 275 represent error rates over multiple packets, whereas the reliability indicator 183 represents error information related to a single packet, e.g., the bits 181. In other implementations, the reliability indicator 183 includes information related to a single packet, e.g., the bits 181, and also includes information related to multiple packets. For example, the reliability indicator 183 may include any combination of per bit, per packet, or per channel quality metrics, such as per bit LLRs, SNRs, average LLR absolute values, BERs, symbol error rates, and/or statistics (e.g., distribution, expected value, variance, a higher-order moment (such as skewness, kurtosis), etc.) based thereon.

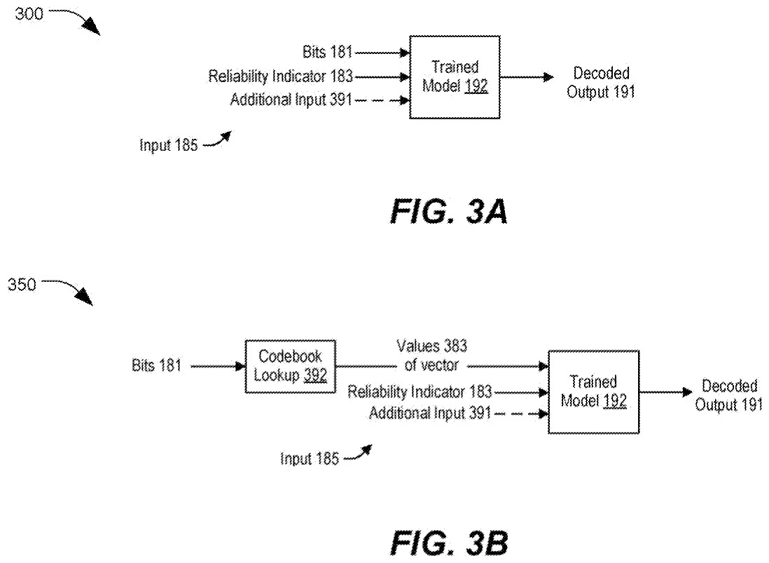

FIGS. 3A and 3B are diagrams of particular aspects of the system of FIG. 1, in accordance with some examples of the present disclosure. In particular. FIG. 3A illustrates an example 300 in which one or more layers of the trained model 192 are trained to determine latent vector values approximating to the encoded time-series data 173 of FIG. 1. In contrast. FIG. 3B illustrates an example 350 in which a codebook lookup 392 distinct from the trained model 192 is performed to determine values of a vector (e.g., the latent vector values) approximating the encoded time-series data 173 of FIG. 1.

In the example 300, the bits 181, the reliability indicator 183, and optionally additional input 391 are provided as the input 185 to the trained model 192 to generate the decoded output 191. In the example 350, the bits 181 are used to perform the codebook lookup 392. In the example 350, a set of two or more of the bits 181 is used to determine a corresponding value 383 of the vector. In the example 350, the vector, the reliability indicator 183, and optionally the additional input 391 are provided as the input 185 to the trained model 192 to generate the decoded output 191. The additional input 391 includes, for example, one or more of the previous model state 210, the previous bits 281, the previous reliability indicator 283 associated with the previous bits 281, the previous decoded output 291, the subsequent bits 271, the subsequent reliability indicator 273 associated with the subsequent bits 271, or the error statistics 275 as described with reference to FIG. 2.

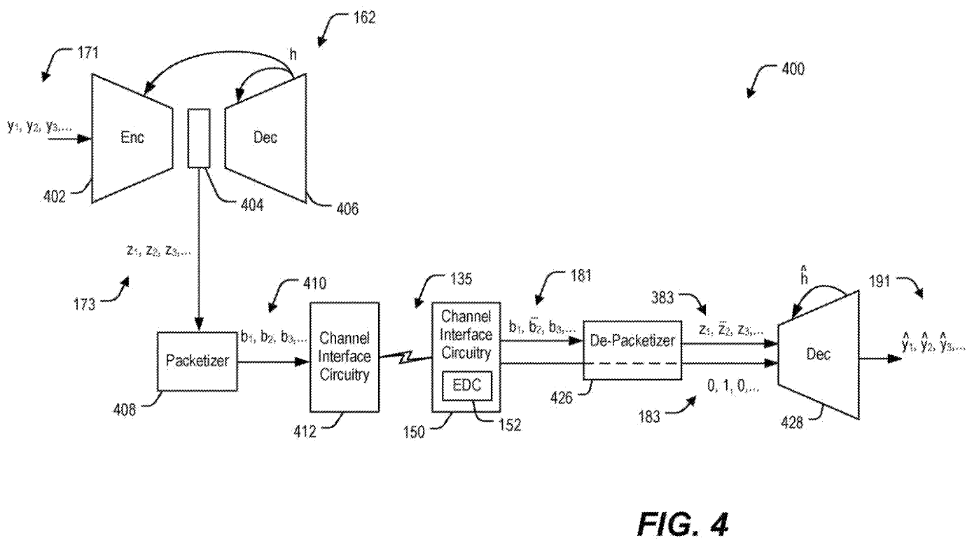

FIGS. 4-9 illustrate various examples of implementations of particular aspects of the system of FIG. 1. Each of FIGS. 4-9 illustrates the encoder 162 as an autoencoder that includes an encoder portion 402, a bottleneck 404, and a decoder portion 406. In each of FIGS. 4-9, the encoder portion 402 is configured to receive input representing the time-series data 171. In particular, the time-series data 171 of FIGS. 4-9 includes a sequence of data sets (yₜ) arranged in order based on time index t of each data set, and each data set (yₜ) represents a time-windowed portion of the time-series data 171. In some implementations, the time-series data 171 includes media data, such as audio data, game data, video data, etc. For example, when the time-series data 171 includes audio data, each time-windowed portion of the time-series data 171 includes data representing features of an audio frame (e.g., a speech frame), such as spectral features (e.g., a complex spectrum, a magnitude spectrum, a mel spectrum, a hark spectrum, etc.), cepstral features (e.g., mel frequency cepstral coefficients, bark frequency cepstral coefficients, etc.), or other data representing a time-windowed portion of an audio waveform. As another example, when the time-series data 171 includes video data, each time-windowed portion of the time-series data 171 includes data representing features of a video frame.

In some implementations, the autoencoder is a feedback recurrent autoencoder (FRAE). In such implementations, in addition to receiving each data set yr, the encoder portion 402 receives feedback from the decoder portion 406, where the feedback includes state data (e.g. one or more hidden states, h) from the decoder portion 406.

The encoder portion 402 of the encoder 162 reduces the dimensionality of data input to the encoder portion 402 to generate one or more latent vectors (zₜ) at the bottleneck 404. In the examples illustrated in FIGS. 4-6, the bottleneck 404 produces one latent vector zₜ for each data set yₜ of the time-series data 171. For example, a latent vector z₁ corresponds to an encoded version of data set y₁ of the time-series data 171, a latent vector z₂ corresponds to an encoded version of data set y₂ of the time-series data 171, a latent vector z₃ corresponds to an encoded version of data set y₃ of the time-series data 171, and so forth.

In FIGS. 7-9, the bottleneck 404 is divided or otherwise configured to produce two or more latent vector zₜⁱ (where i is an index distinguishing the two or more latent vectors and subsequently derived data) for each data set yₜ of the time-series data 171. For example, in FIGS. 7-9, the data set y₁ of the time-series data 171 is encoded to generate latent vectors z₁¹ and z₁², the data set y₂ of the time-series data 171 is encoded to generate latent vectors z₂¹ and z₂², the data set y₃ of the time-series data 171 is encoded to generate latent vectors z₃¹ and z₃², and so forth.

Each latent vector zₜ of the encoded time-series data 173 is provided to a packetizer 408 to generate a set of bits 410 (bₜ) representing values of the latent vector zₜ, and channel interface circuitry 412 (e.g., components of a physical layer of the device 160 of FIG. 1) sends a signal 135 representing the bits 410 via a communication channel (e.g., a wired or wireless communication channel). For example, the channel interface circuitry 412 modulates the signal 135 to represent the bits 410 as a set of symbols in the modulated signal 135.

The channel interface circuitry 150 is configured to receive the signal 135 and to demodulate the signal 135 to determine bits represented by the symbols in the received signal 135. The EDC 152 checks the bits determined by the channel interface circuitry 150 for each packet to detect and/or correct errors (e.g., one or more flipped bits in the packet). If the EDC 152 detects no errors or if the EDC 152 is able to correct all detected errors, the channel interface circuitry 150 outputs the bits 181 of the packet (e.g., bits b₁ for a first packet, bits b₂, for a second packet, and so forth) and the reliability indicator 183 indicating that the bits 181 of the packet are reliable. If the EDC 152 detects one or more errors in the packet that it is not able to correct, the channel interface circuitry 150 outputs estimated bits 181 (denoted by a bar over the vector in FIGS. 4-9, such as “b̅₂” in FIG. 4) of the packet and the reliability indicator 183 indicating that the bits 181 of the packet include at least one error.

In each of FIGS. 4-9, the bits 181 are provided to a de-packetizer 426, which is configured to perform a codebook lookup based on the bits 181 to determine values 383 of a latent vector zₜ represented by the bits 181 of a packet. For example, values 383 of a first latent vector z₁ am determined based on the bits b₁ (or estimated bits b̅₁) of a first packet, values 383 of a second latent vector z₂ are determined based on the bits b₂ (or estimated bits b̅₂) of a second packet, and so forth. As explained with reference to FIGS. 3A and 3B, in some implementations, the codebook lookup is performed by one or more layers of the trained model 192 of FIGS. 1-3B. In such implementations, the de-packetizer 426 corresponds to, includes, or is included within the one or more layers of the trained model 192 that perform the codebook lookup.

In each of FIGS. 4-9, the values 383 of a latent vector zₜ representing a packet and the reliability indicator 183 associated with the latent vector zₜ are provided as input to a decoder neural network 428 to generate the decoded output 191. For example, at a first time, the first latent vector zi and a reliability indicator 183 associated with first latent vector z₁ are input to the decoder neural network 428 to generate a first output vector ŷ₁ of the decoded output 191, at a second time, the second latent vector z₂ and a reliability indicator 183 associated with the second latent vector z₂ are input to the decoder neural network 428 to generate a second output vector ŷ₂ of the decoded output 191, and so forth. Each output vector ŷₜ represents an estimate (as denoted by the “Δ” symbol over each output vector) of a corresponding portion of the time-series data 171. For example, the first output vector ŷ₁ represents an estimate of a first portion y₁ of the time-series data 171, the second output vector ŷ₂ represents an estimate of a second portion y₂ of the time-series data 171, and so forth.

In some implementations, the decoder neural network 428 corresponds to a feedback recurrent network. In such implementations, in addition to receiving the values 383 of a latent vector zₜ and the reliability indicator 183 associated with the latent vector zₜ, the decoder neural network 428 receives feedback including state data (e.g. one or more hidden states, ĥ) based on one or more prior inference operations performed by the decoder neural network 428. In sonic implementations, in addition to receiving the values 383 of a latent vector k and the reliability indicator 183 associated with the latent vector zₜ, the decoder neural network 428 receives additional input (e.g., additional input 391 of FIGS. 3A and 3B).

Referring to FIG. 4, a diagram illustrating a system 400 is shown. In the example illustrated in FIG. 4, the reliability indicator 183 includes a packet-level indicator. For example, in FIG. 4, bits associated with a first packet do not include any errors (as denoted by bi, where the absence of a bar over the “b” indicates that the bits do not include errors), and bits associated with a second packet include one or more errors (as denoted by b̅₂, where the bar over the “b” indicates that the bits include errors). In this example, a value of the reliability indicator 183 associated with the first packet is a 0 indicating that the bits bi associated with the first packet are reliable (e.g., do not include errors). Further, in this example, a value of the reliability indicator 183 associated with the second packet is a 1 indicating that the bits b̅₂ associated with the second packet include errors.

In FIG. 4, the values 383 of the latent vectors zₜ are determined based on the bits bₜ associated with each packet, and the values 383 of the latent vectors zₜ and the values of the reliability indicator 183 associated with each packet are provided as input to the decoder neural network 428. As explained above, in some implementations, the additional input 391 may also be provided as input to the decoder neural network 428. For example, input to the decoder neural network 428 may include information regarding one or more previously decoded packets, information regarding one or more subsequent packets, model states, error statistics, other information associated with the reliability of the channel, one or more particular packets, or one or more particular bits, or any combination thereof.

In a particular implementation, the additional input 391 provided to the decoder neural network 428 includes channel statistics, such as a block error rate (BLER) associated with a set of previously received packets. In this example, the BLER provides information regarding the probability of various numbers of errors associated with a packet that includes one or more uncorrectable errors. However, this simulation also indicates that as the BLER of the channel increases, so does the likelihood of a packet have a larger percentage of flipped bits. For example, according to this simulation, when the BLER of the channel is 20%, about 80% of packets have a BER of 0%, a bit over 4% of packets have a BER of between 0 and 0.1, almost 8.5% of packets have a BER of between 0.1 and 0.2, and almost 8% of packets have a BER of between 0.2 and 0.4. Providing information about the BLER or other channel statistics may enable the decoder neural network 428 to adjust its decoding process to be appropriate for the particular channel conditions under which a packet with uncorrectable errors is received.

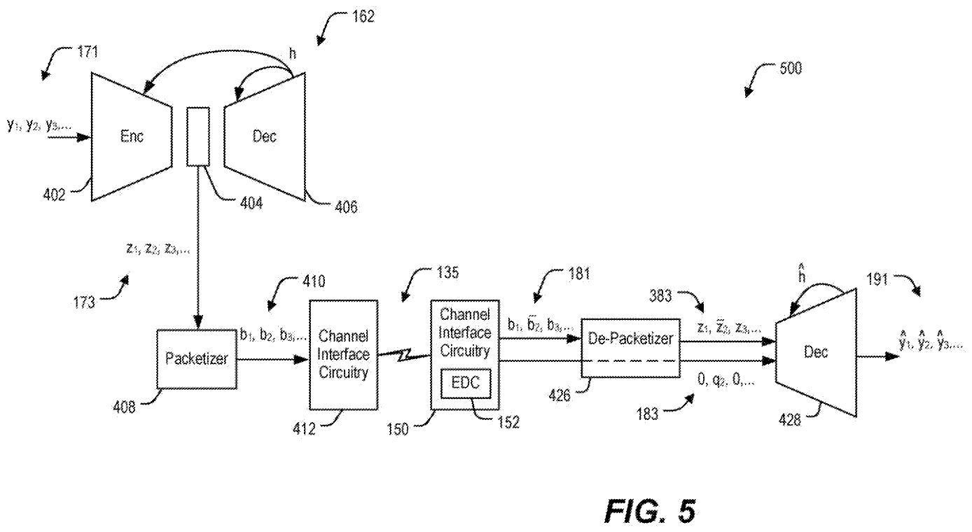

Referring to FIG. 5, a diagram illustrating a system 500 is shown. In the example illustrated in FIG. 5, the reliability indicator 183 includes a packet-level indicator. For example, in FIG. 5, bits bi associated with a first packet do not include any errors, and bits b̅₂ associated with a second packet include one or more errors. In this example, the reliability indicator 183 associated with the first packet has a first value (e.g., a 0 in FIG. 5) indicating that the bits bi associated with the first packet do not include errors, and the reliability indicator 183 associated with the second packet is q₂, where q represents one or more values of a quality metric associated with a packet that include errors. Examples of quality metrics that can be used to determine value(s) of q include, without limitation, estimated SNR of the signal 135 when the packet was received, average LLR absolute value associated with the packet, estimated BER associated with the packet, estimated symbol error rate associated with the packet, one or more other metrics indicating an estimate of the number of incorrect bits associated with the packet, or any combination thereof.

In FIG. 5, the values 383 of the latent vectors it are determined based on the bits bₜ associated with each packet, and the values 383 of the latent vectors zₜ and the values of the reliability indicator 183 associated with each packet are provided as input to the decoder neural network 428. As explained above, in some implementations, the additional input 391 may also be provided as input to the decoder neural network 428. For example, input to the decoder neural network 428 may include information regarding one or more previously decoded packets, information regarding one or more subsequent packets, model states, error statistics, other information associated with the reliability of the channel, one or more particular packets, or one or more particular bits, or any combination thereof.

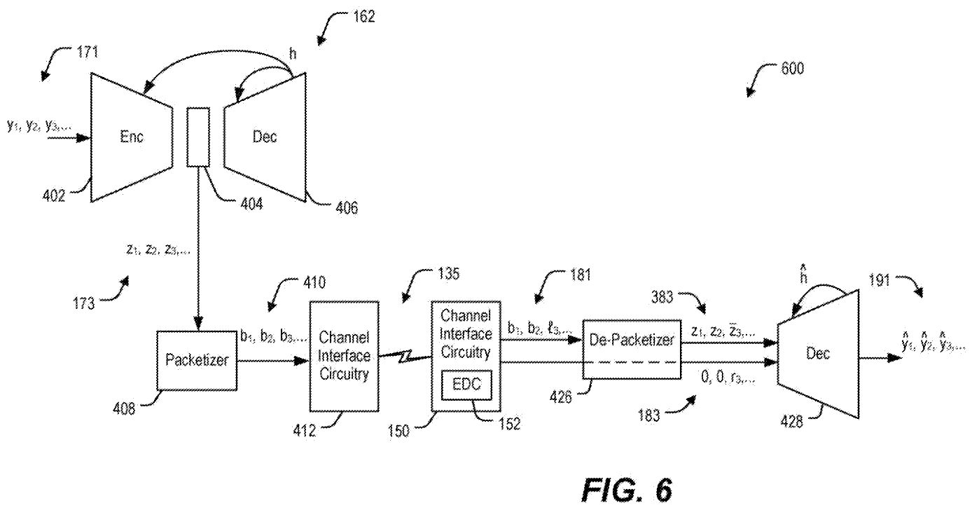

Referring to FIG. 6, a diagram illustrating a system 600 is shown. In the example illustrated in FIG. 6, at least the bits 181 of packets with uncorrectable errors (e.g., a third packet in FIG. 6) are represented by soft bits. In this context, a “soft bit” refers to one or more values indicating an estimate of a probability that a particular bit has a particular value. As one example, a soft bit may include a value that indicates a probability that a bit of a packet is a 0. In some implementations, the EDC 152 determines an LLR for each bit of a packet based on symbols received via the signal 135. In such implementations, at least for packets with uncorrectable errors, the LLRs of the packet may be output by the channel interface circuitry 150 as soft bits (denoted l₁ in FIG. 6) representing the packet.

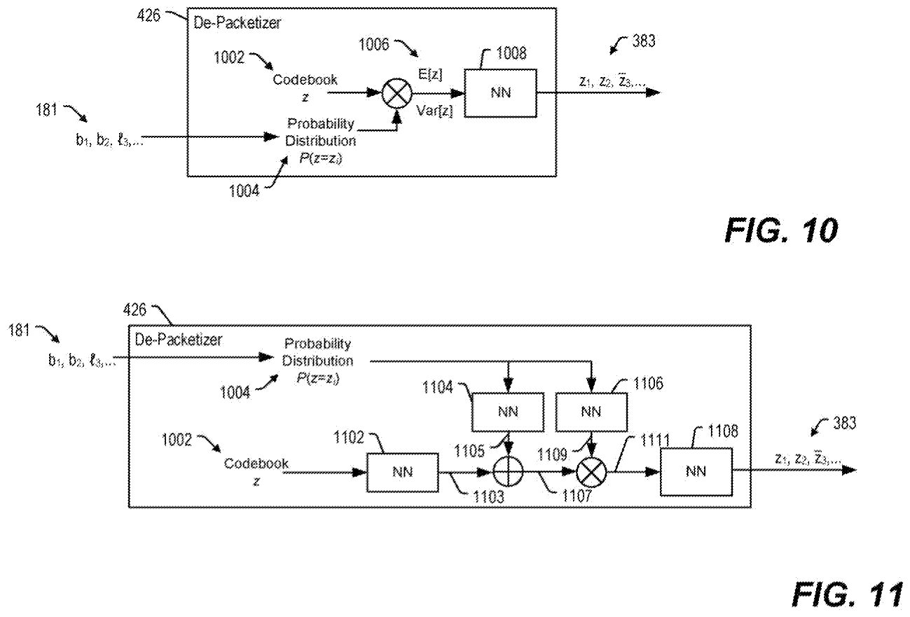

In the example of FIG. 6, the bits 181 (whether hard bits or soft bits) associated with each packet are mapped to values 383 of the latent vectors zₜ. Several processes to map soft bits to values 383 of the latent vectors zₜ are described below with reference to FIGS. 10 and 11. The values 383 of the latent vectors zₜ and the reliability indicator 183 (denoted rₜ in FIG. 6) associated with each packet are provided as input to the decoder neural network 428. In the example of FIG. 6, the reliability indicator 183 may include a bit-level reliability indicator or a packet-level reliability indicator. For example, for packets with no uncorrectable errors (such as the first and second packets in FIG. 6), the reliability indicator 183 can include a null or default value for the packet indicating that the packet includes no errors or can include a null or default value for each bit of a packet indicating that the bit includes no errors. In this example, for a packet with one or more uncorrectable errors (such as the third packet in FIG. 6), the reliability indicator 183 can include single value for the packet indicating that the packet includes errors or can include a value for each bit of a packet (such as an UR for each bit). As another example, the reliability indicator 183 associated with a packet that include errors may include one or more values of a quality metric, as described with reference to FIG. 5.

In some implementations, the additional input 391 may also be provided as input to the decoder neural network 428 of FIG. 6. For example, input to the decoder neural network 428 may include information regarding one or more previously decoded packets, information regarding one or more subsequent packets, model states, error statistics, other information associated with the reliability of the channel, one or more particular packets, or one or more particular bits, or any combination thereof.

As explained above, in FIGS. 7-9, the bottleneck 404 is divided or otherwise configured to produce two or mow latent vector z₁¹ for each data set y, of the time-series data 171. For example, the encoded time-series data 173 includes first encoded time-series data 173A and second encoded time-series data 173B. In this example, the first encoded time-series data 173A includes latent vector z₁¹ encoding a first portion (e.g., a first set of one or more features) of data set y₁ of the time-series data 171, latent vector z₁¹ encoding a first portion of data set y₂ of the time-series data 171, and latent vector z₁¹ encoding a first portion of data set y₃ of the time-series data 171. Further, the second encoded time-series data 173B includes latent vector z₁¹ encoding a second portion (e.g., a second set of one or more features) of data set y₁ of the time-series data 171, latent vector z₂² encoding a second portion of data set y₂ of the time-series data 171, and latent vector z₃² encoding a second portion of data set y₃ of the time-series data 171. Although FIGS. 7-9 illustrate each data set yₜ of the time-series data 171 being encoded to generate two latent vectors zₜⁱ, in other implementations, each data set yₜ is encoded to generate more than two latent vectors zₜⁱ.

In some implementations, the two or more latent vectors zₜ^{l} associated with a data set yₜ of the time-series data 171 are configured (e.g., based on training of the encoder 162) to be decodable together to reproduce the data set yₜ of the time-series data 171 with a first fidelity (e.g., high fidelity) or to be decodable separately to reproduce the data set yₜ of the time-series data 171 with a second fidelity (e.g., lower fidelity). In a particular aspect, the encoder 162 is configured and trained such that accuracy of reproduction of the time-series data 171 is more heavily dependent on content of the first encoded time-series data 173A than on content of the second encoded time-series data 17313. For example, when the time-series data 171 includes speech, some speech parameters are more important than others for reproduction of speech that is readily understandable by a human listener. In this example, the more important speech parameters may be encoded in (or more heavily represented in) latent vectors z₁¹ of the first encoded time-series data 173A, and less important speech parameters may be encoded in (or more heavily represented in) latent vectors z₁¹ of the second encoded time-series data 173B. In each of FIGS. 7-9, the encoder 162 is a trained machine-learning model, and the content of the latent vectors z₁¹ is dependent upon and related to the entire content of each data set yₜ of the time-series data 171. Thus, the example above of more important speech parameters encoded in the latent vectors z₁¹ of the first encoded time-series data 173A and less important speech parameters encoded in the latent vectors z₁¹ of the second encoded time-series data 1738 is merely illustrative.

In implementations in which the latent vectors z₁¹ of the first encoded time-series data 173A are more important to accurate reproduction of the time-series data 171 than the latent vectors z₁¹ of the second encoded time-series data 173B, the latent vectors z₁¹ of the first encoded time-series data 173A may be more protected for transmission than the latent vectors z, of the second encoded time-series data 1731. For example, in some such implementation, the latent vectors z₁¹ of the first encoded time-series data 173A may be fully protected for transmission; whereas the latent vectors z₁¹ of the second encoded time-series data 173B may be only partially protected for transmission. In this context, a protection level (or degree of protection) for transmission associated with particular data refers to a maximum bit error rate that can be corrected for the particular data. For example, fully protected data can be recovered (e.g., by EDC 152 on a receiving device) even if every bit of the data is flipped. One way to fully protect data is via redundant transmission of the data. Additionally, various degrees of protection (up to and including full protection) can be achieved via different error correction coding schemes. Although some protection schemes are more efficient than others, generally, providing a greater degree of protection (e.g., a higher protection level) entails transmitting more bits.

In FIGS. 7-9, the first encoded time-series data 173A is provided to a first packetizer 408A to generate first bits 410A, and the first bits 410A are provided to the channel interface circuitry 412 for transmission via a first signal 135A. Additionally, the second encoded time-series data 173B is provided to a second packetizer 408B to generate second bits 410B, and the second bits 410B are provided to the channel interface circuitry 412 for transmission via a second signal 135B. In a particular aspect, the channel interface circuitry 412 or another component of the transmitting device is configured to perform one or more operations (e.g., error coding, redundant transmission, etc.) to apply a first protection level to the first bits 410A for transmission and to perform one or more operations to apply a second protection level to the second bits 410B for transmission. When the latent vectors z₁¹ of the first encoded time-series data 173A are more important to accurate reproduction of the time-series data 171 than the latent vectors z₁¹ of the second encoded time-series data 1738, the first protection level may be higher than (e.g., enable recovery of more bits than) the second protection level.

The channel interface circuitry 150 is configured to receive the first signal 135A and to demodulate the first signal 135A to determine first bits 181A represented by symbols in the first signal 135A. The channel interface circuitry 150 is also configured to receive the second signal 135B and to demodulate the second signal 135B to determine second bits 181B represented by symbols in the second signal 135B. The first bits 181A correspond to received versions of the first bits 410A, and the second bits 181B correspond to received versions of the second bits 4108. Although FIGS. 7-9 illustrate two distinct signals 135A, 135B used to communicate the bits 410A and 410B, in some implementations, the bits 410A and 410B are communicated via the same signal or set of signals 135. Accordingly, the first and second signals 135A. 135B may alternatively be referred to herein as first and second channels 135A. 1358, where channels can be logically or physically distinguished.

In the example illustrated in FIGS. 7-9, first EDC 152A of the channel interface circuitry 150 is configured to check each packet of the first bits 181A to detect and/or correct errors (e.g., one or more flipped bits in the packet) based on the first protection level applied to the first bits 410A. If the first EDC 152A detects no errors or if the first EDC 152A is able to correct all detected errors, the channel interface circuitry 150 outputs the first bits 181A of the packet (e.g., bits b₁¹ for a first packet, bits b₂¹, for a second packet, and so forth) and the reliability indicator 183A indicating that the bits 181A of the packet are reliable. If the first EDC 152A detects one or mor errors in the packet that it is not able to correct, the channel interface circuitry 150 outputs estimated bits 181A (denoted by a bar, such as “b̅₂²” in FIG. 7) of the packet and the reliability indicator 183A indicating that the bits 181A of the packet include at least one error.

Likewise, second EDC 152B of the channel interface circuitry 150 is configured to check each packet of the second bits 1818 to detect and/or correct errors based on the second protection level applied to the second bits 410B. If the second EDC 152B detects no errors or if the second EDC 152B is able to correct all detected errors, the channel interface circuitry 150 outputs the bits 1818 of the packet (e.g., bits b₁² for a first packet, bits b₂², for a second packet, and so forth) and the reliability indicator 183B indicating that the bits 181B of the packet are reliable. If the second EDC 152B detects one or more errors in the packet that it is not able to correct, the channel interface circuitry 150 outputs estimated bits 181B (denoted by a bar, such as “b̅₂²” in FIG. 7) of the packet and the reliability indicator 183B indicating that the bits 181B of the packet include at least one error.

In each of FIGS. 7-9, the first bits 181A are provided to a first de-packetizer 426A to determine values 383A of a latent vector z₁¹ represented by the first bits 181 of a packet from the first channel 135A, and the second bits 181B are provided to a second de-packetizer 426B to determine values 383B of a latent vector z₁¹ represented by the second bits 18113 of a packet from the second channel 1358. In some implementations, the de-packetizers 426A. 426B correspond to, include, or are included within one or more layers of a trained model (such as one or more layers of the decoder neural network 428).

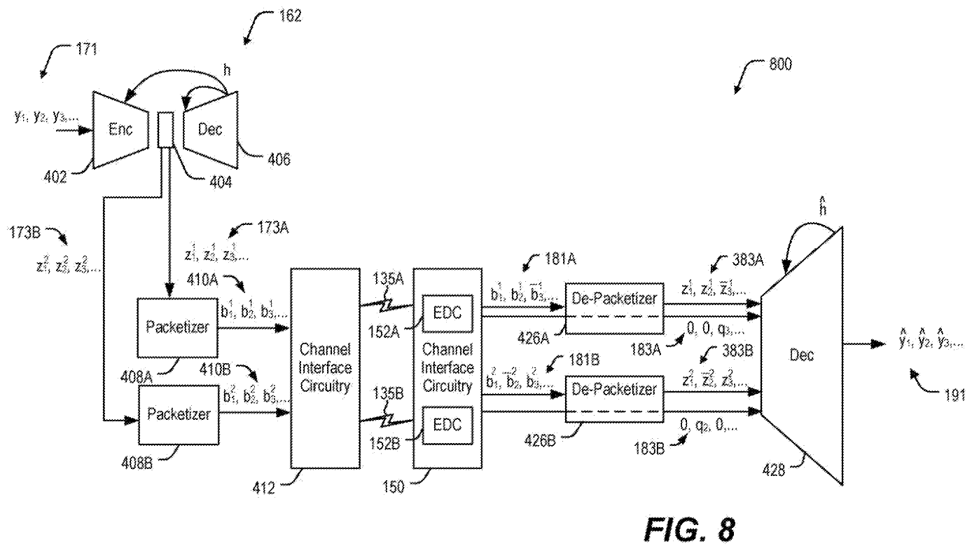

In the examples illustrated in FIGS. 7 and 8, the values 383A of the latent vector zₜ^{l}, the reliability indicator 183A associated with the values 383A of the latent vector zₜ^{l}, the values 383B of a latent vector zₜ², and the reliability indicator 1838 associated with the values 383B of the latent vector zₜ² are provided as input to the decoder neural network 428. In these examples, the decoder neural network 428 generates the output vector ŷₜ of the decoded output 191 based on the input to the decoder neural network 428. In some implementations, the input to the decoder neural network 428 may also include the additional input 391.

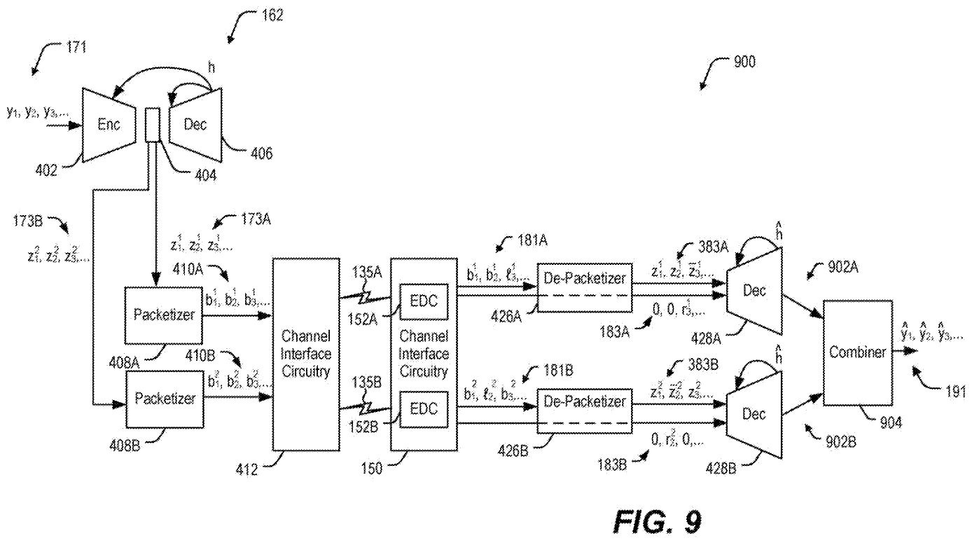

In the example illustrated in FIG. 9, the values 383A of the latent vector z₁¹ and the reliability indicator 183A associated with the values 383A of the latent vector z₁¹ are provided as input to a first decoder neural network 428A, and the values 383B of a latent vector z₁¹ and the reliability indicator 1838 associated with the values 383B of the latent vector z₁¹ are provided as input to a second decoder neural network 428B. In this example, the first decoder neural network 428A generates an intermediate output 902A based on the input to the first decoder neural network 428A, and the second decoder neural network 428B generates an intermediate output 902B based on the input to the second decoder neural network 428B. The intermediate outputs 902A, 902B are provided as input to a combiner 904 that is configured to combine the intermediate outputs 902A, 902B to generate the output vector ŷₜ of the decoded output 191. The combiner 904 may include a trained model (e.g., a neural network) that is configured (and trained) to combine the intermediate outputs 902A. 902B. In some implementations, the input to the first decoder neural network 428A, the input to the second decoder neural network 428B, or both, may also include the additional input 391.

Referring to FIG. 7, a diagram illustrating a system 700 is shown. In the example illustrated in FIG. 7, the reliability indicators 183A, 183B include packet-level indicators. For example, a value of the reliability indicator 183A associated with a first packet of the first channel is a 0 indicating that the bits b₁¹ associated with the first packet of the first channel do not include errors, and a value of the reliability indicator 183A associated with a third packet of the first channel is a I indicating that the bits b₃¹ associated with the third packet of the first channel include one or more errors. Thus, the system 700 is similar to a multichannel implementation of the system 400 of FIG. 4.

In some implementations of the system 700, the channels are associated with different levels of protection, as explained above. To illustrate, in some such implementations, the first channel (associated with the first bits 181A) may represent information that is mom important for high quality reproduction of the time-series data 171 than is information represented by the second channel (associated with the second bits 181B). In this example, a higher protection level may be used for the first channel than is used for the second channel.

Referring to FIG. 8, a diagram illustrating a system 800 is shown. In the example illustrated in FIG. 8, the reliability indicators 183A. 183B include packet-level indicators that represent one or more values of a quality metric associated with a packet that includes errors. Thus, the system 800 is similar to a multichannel implementation of the system 500 of FIG. 5. In this multichannel implementation (e.g., the system 800) the channels may be associated with different levels of protection, as explained above. Additionally, in the system 800, different quality metrics can be used for the different channels.

Referring to FIG. 9, a diagram illustrating a system 900 is shown. In the example illustrated in FIG. 9, at least the bits 181 of packets with uncorrectable errors (e.g., a third packet

$${ℓ}_{3}^{1}$$

of the first channel or a second packet

$${ℓ}_{2}^{2}$$

of the second channel in FIG. 9) are represented by soft bits. For example, the soft bits may include LLRs for each bit of a packet. Thus, the system 900 is similar to a multichannel implementation of the system 600 of FIG. 6. In this multichannel implementation (e.g., the system 900) the channels may be associated with different levels of protection, as explained above. Additionally, in the system 90, different reliability indicators 183 can be used for the different channels.

While each of FIGS. 7-9 illustrates two channels of data being decoded to generate the decoded output 191, in other multichannel implementations, more than two channels of data are decoded to generate the decoded output 191. Additionally, although FIGS. 7 and 8 illustrate a single decoder neural network 428 that decodes the multichannel data, in other implementations, the system 700, the system 800, or both, use multiple decoder neural networks 428 (such as the first decoder neural network 428A and the second decoder neural network 428B of FIG. 9) and the combiner 904 to generate the decoded output 191. Further, although FIG. 9 illustrates an implementation of the system 900 that includes the first decoder neural network 428A, the second decoder neural network 428B, and the combiner 904 to generate the decoded output 191, in other implementations, the system 900 uses a single decoder neural network 428 as in FIGS. 7 and 8.

FIG. 10 is a diagram of particular aspects of the system of FIG. 1, in accordance with sonic examples of the present disclosure. In particular. FIG. 10 illustrates an example of a de-packetizer 426 that is configured to generate values 383 of the latent vectors zₜ based on bits 181 that include soft bits [symbol] at least for packets with uncorrectable errors.

In the example illustrated in FIG. 10, a third packet includes one or more uncorrectable errors. Accordingly, the third packet is represented by soft bits in the bits 181, as denoted by l₃ in FIG. 10. In FIG. 10, the de-packetizer 426 determines expected vector values (E[z]) based on a codebook 1002 of latent vector values z and a probability distribution 1004. The probability distribution 1004 indicates, for each codebook value zᵢ, a probability that the soft bits represent that codebook value zᵢ. For example, for a 4-value codebook where each latent vector value zₜ is represented by two bits, a latent vector value x₀ can be represented by bits (00), a latent vector value z₁ can be represented by bits (01), a latent vector value z₂ can be represented by bits (10), and a latent vector value z₃ can be represented by bits (11). In this example, the probability distribution 1004 can be determined as:

$$P ( z = {z}_{0} ) = {p}_{0} {p}_{1}$$

$$P ( z = {z}_{1} ) = {p}_{0} ( 1 - {p}_{1} )$$

$$P ( z = {z}_{2} ) = ( 1 - {p}_{0} ) {p}_{1}$$

$$P ( z = {z}_{3} ) = ( 1 - {p}_{0} ) ( 1 - {p}_{1} )$$

$$where {p}_{0} = P ( {b}_{0} = 0 ) and {p}_{1} = P ( {b}_{1} = 0 ) .$$

In FIG. 10, the expected vector values (E[z]) based on the soft bits lₜ are provided is input 1006 to a (rained model (e.g. a neural network (NN) 1008 in FIG. 10) to determine corresponding estimated latent vector values z̅ₜ. In some implementations, a variance of the vector values (Var[z]) is also included in the input 1006 to the trained model, in which case the trained model determines the estimated latent vector values z̅ₜ based on the expected vector values (E[z]) and the variance of the vector values (Var[z]). In such implementations, the variance of the vector values (Var[z]) can be determined as Var[z]=E[(z−E[z])²].

In some implementations, the bits 181 associated with packets that do not include any uncorrected errors are processed in the same manner, and since each bit is known, the probability that the bit=0 will be either 1 or 0. As a result, the expected vector values (E[z]) 1006 based on such bits (e.g., bits bi associated with a first packet in FIG. 10) correspond to a hard decision of the corresponding latent vector values zₜ.

FIG. 1I is a diagram of particular aspects of the system of FIG. 1, in accordance with some examples of the present disclosure. In particular. FIG. 11 illustrates another example of a de-packetizer 426 that is configured to generate values 383 of the latent vectors a based on bits 181 that include soft bits lₜ at least for packets with uncorrectable errors. The example illustrated in FIG. 11 uses a condition layer (e.g. one or more neural network layers) based on a conditioning variable (e.g., LLR values of soft bits) to shift and scale input 1111 to a neural network 1108 that determines the values 383 of the latent vectors zₜ. In FIG. 11, the shifting and scaling are condition-dependent, which enables (among other things) gating for some neurons of the neural network 1108,

In the example illustrated in FIG. 11, a third packet includes one or more uncorrectable errors. Accordingly, the third packet is represented by soft bits in the bits 181, as denoted by l₃ in FIG. 11. In FIG. 11, the de-packetizer 426 obtains values based on the codebook 1002 and projects the values based on the codebook 1002 into a latent space using a neural network 1102 to generate output 1103.

The de-packetizer 426 determines the probability distribution 1004 based on the soft bits lₜ at least for packets with uncorrectable errors (e.g., the third packet in FIG. 11) as described with reference to FIG. 10. The probability distribution 1004 is provided as input to a neural network 1104 to generate output 1105. The output 1105 is applied to the output I 103 to shift the output 1103 to generate an output 1107. In a particular implementation, the neural network 1104 includes two layers, such as a linear layer fully connected to a layer that applies a non-linear activation function, such as a ReLU activation function.

The probability distribution 1004 is also provided as input to a neural network 1106 to generate output 1109. The output 1109 is applied to the output 1107 to scale the output 1107 to generate the input 1111 of the neural network 1108. In a particular implementation, the neural network 1106 includes two layers, such as a linear layer fully connected to a layer that applies a non-linear activation function, such as a sigmoid activation function. The neural network 1108, in FIG. 11, is trained to generate the values 383 of the latent vectors z based on the input 1111.

In some implementations, the bits 181 associated with packets that do not include any uncorrected errors are processed in the same manner, and since each bit is known, the probability that the bit=0 will be either 1 or 0.

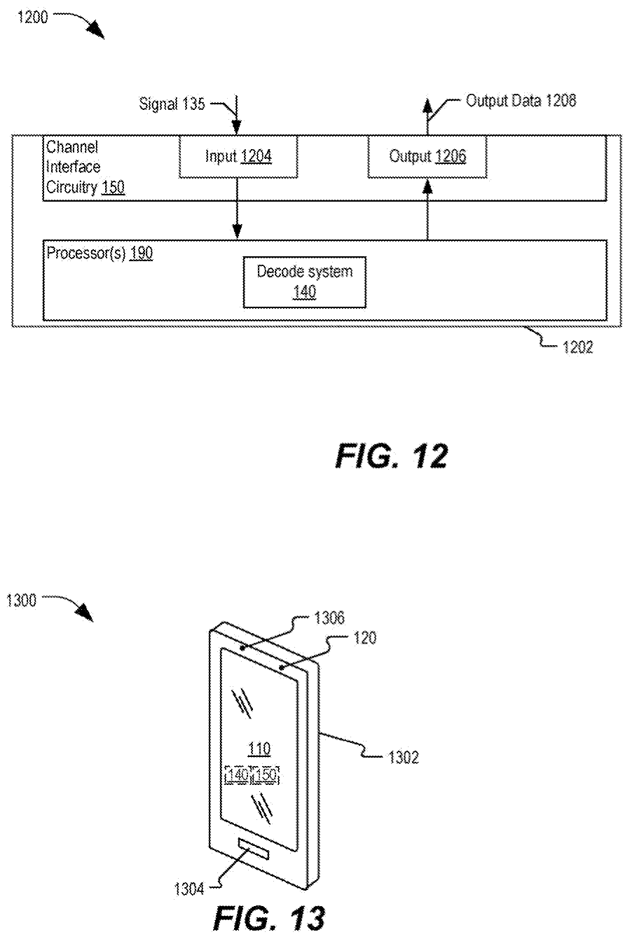

FIG. 12 depicts an implementation 1200 of the device 102 as an integrated circuit 1202 that includes the channel interface circuitry 150 and the one or more processors 190. The integrated circuit 1202 includes a signal input 1204, such as one or more bus interfaces, one or more antennas, or other circuitry, to receive the signal 135. The integrated circuit 1202 also includes an output 1206, such as a bus interface, one or more antennas, or other circuitry, to enable sending of output data 1208, such as the output representing the decoded output 191 (e.g., the media data 128 of FIG. 1). In the example illustrated in FIG. 12, the processors) 190 include the decode system 140. For example, the processor(s) 190 may include the trained model 192 of any of FIGS. 1-3B, which may include for example, any of the decoder networks 428 of FIGS. 4-9, and optionally may include any of the de-packetizers 426 of FIGS. 4-9, the combiner 904 of FIG. 9, or combinations thereof.

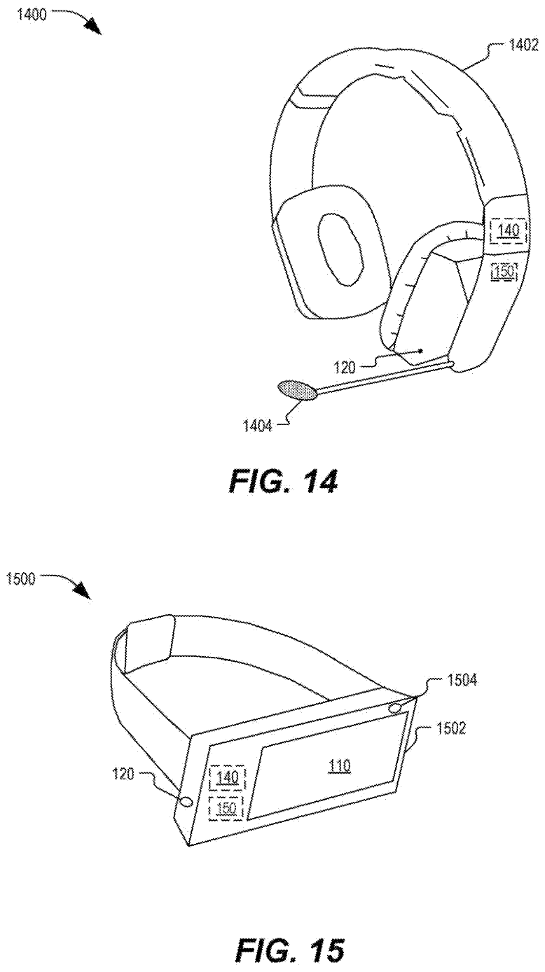

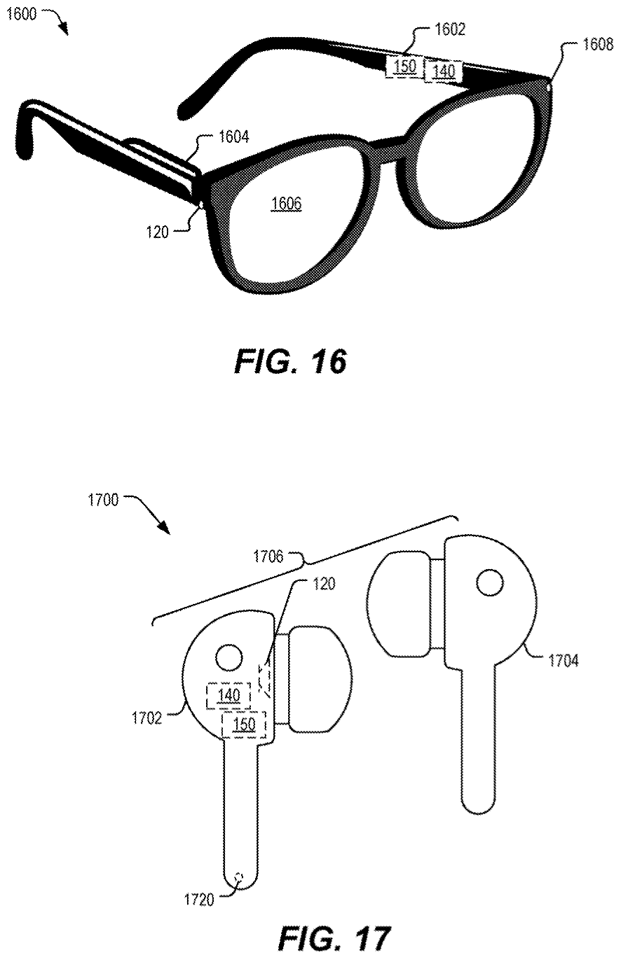

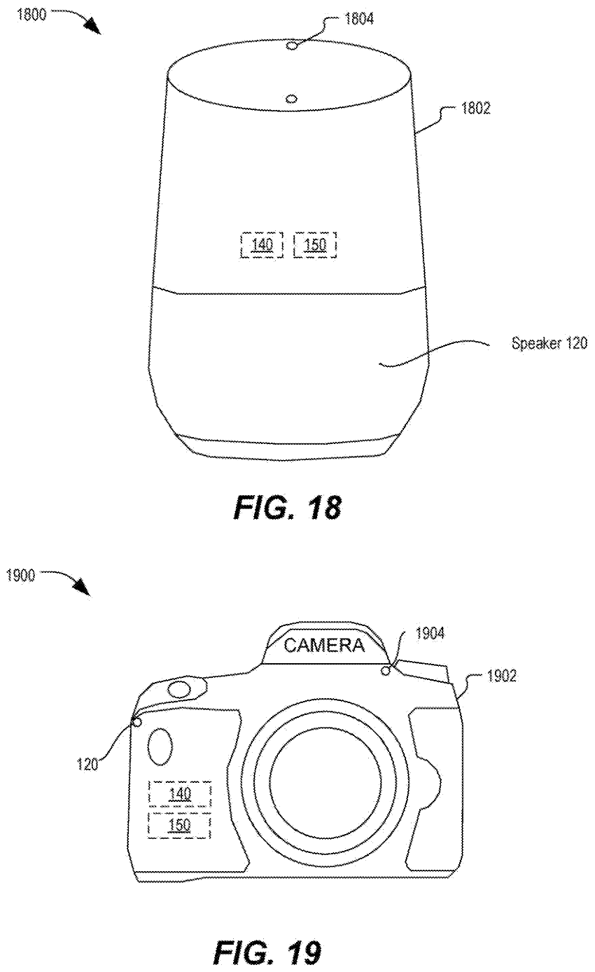

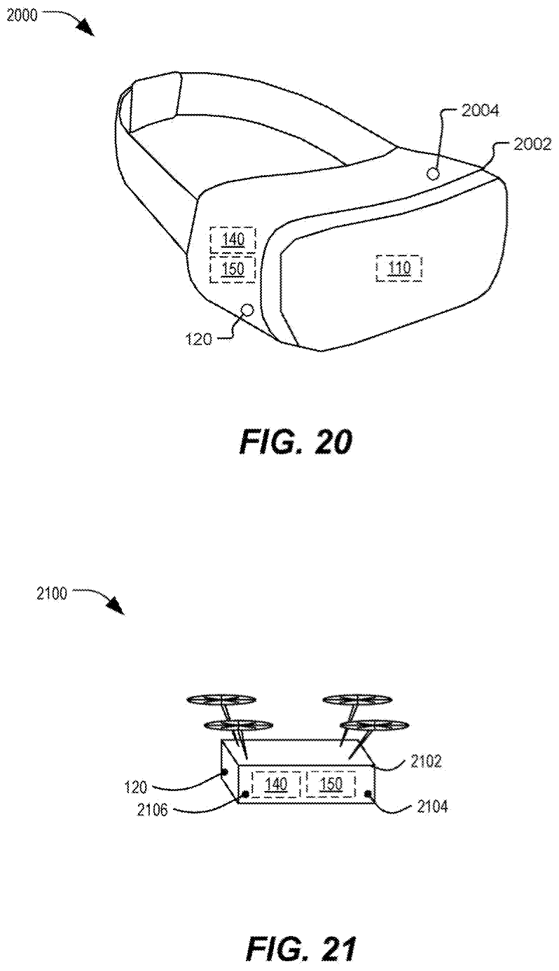

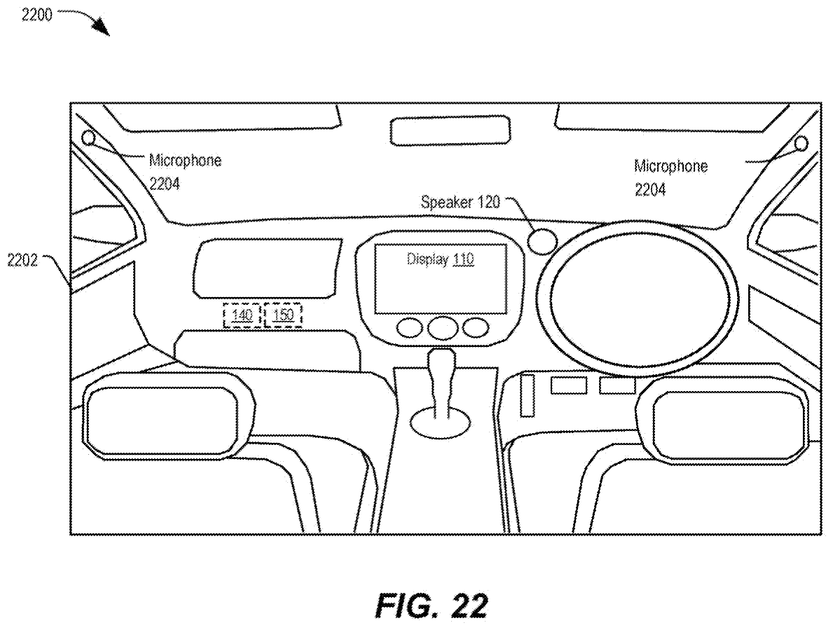

The integrated circuit 1202 can be integrated within one or more other devices, such as a mobile phone or tablet as depicted in FIG. 13, a headset as depicted in FIG. 14, a wearable electronic device as depicted in FIG. 15, a mixed reality or augmented reality glasses device as depicted in FIG. 16, earbuds as depicted in FIG. 17, a voice-controlled speaker system as depicted in FIG. 18, a camera as depicted in FIG. 19, a virtual reality, mixed reality, or augmented reality headset as depicted in FIG. 20, or a vehicle as depicted in FIG. 21 or FIG. 22, to enable such other devices to decode encoded time-series data.

FIG. 13 depicts an implementation 1300 in which the device 102 includes a mobile device 1302, such as a phone or tablet, as illustrative, non-limiting examples. The mobile device 1302 includes a microphone 1304, a camera 1306, the speaker 120, and the display 110. Components of the system 100 of FIG. 1, including the decode system 140 and the channel interface circuitry 150, are integrated in the mobile device 1302 and are illustrated using dashed lines to indicate internal components that are not generally visible to a user of the mobile device 1302. In a particular example, the channel interface circuitry 150 is operable to receive a signal transmitted to the mobile device 1302 and to obtain, based on the signal, first bits representing first encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example. signals based on the decoded output can be provided to the display 110, to the speaker 120, or both, for presentation to a user.

FIG. 14 depicts an implementation 1400 in which the device 102 includes a headset device 1402. The headset device 1402 includes a microphone 1404 and the speaker 120. Components of the system 100 of FIG. 1, including the decode system 140 and the channel interface circuitry 150, are integrated in the headset device 1402. In a particular example, the channel interface circuitry 150 is operable to receive a signal transmitted to the headset device 1402 and to obtain, based on the signal, first bits representing first encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example, signals (e.g., the audio data 126 of FIG. 1) based on the decoded output can be provided to the speaker 120 for presentation to a user.

FIG. 15 depicts an implementation 1500 in which the device 102 includes a wearable electronic device 1502, illustrated as a “smart watch.” The wearable electronic device 1502 includes a microphone 1504, the speaker 120, and a display 110. Components of the system 1X) of FIG. 1, including the decode system 140 and the channel interface circuitry 150, am integrated in the wearable electronic device 1502. In a particular example, the channel interface circuitry 150 is operable to receive a signal transmitted to the wearable electronic device 1502 and to obtain, based on the signal, first bits representing first encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example, signals based on the decoded output can be provided to the display 110, to the speaker 120, or both, for presentation to a user.

FIG. 16 depicts an implementation 1600 in which the device 102 includes a portable electronic device that corresponds to augmented reality or mixed reality glasses 1602. The glasses 1602 include a microphone 1608 and a holographic projection unit 1604 configured to project visual data onto a surface of a lens 1606 or to reflect the visual data off of a surface of the lens 1606 and onto the wearer's retina. Components of the system 100 of FIG. 1, including the speaker 120, the decode system 140, and the channel interface circuitry 150, are integrated in the glasses 1602. In a particular example, the channel interface circuitry 150 is operable to receive a signal transmitted to the glasses 1602 and to obtain, based on the signal, first bits representing first encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example, signals based on the decoded output can be provided to the speaker 120 for presentation to a user. Additionally, or alternatively, the signals based on the decoded output can be provided to the holographic projection unit 1604 for projection onto the surface of the lens 1606.

FIG. 17 depicts an implementation 17(0 in which the device 102 includes a portable electronic device that corresponds to a pair of earbuds 1706 that includes a first earbud 1702 and a second earbud 1704. Although earbuds are described, it should be understood that the present technology can be applied to other in-car or over-ear playback devices.

The first earbud 1702 includes the speaker 120 and a microphone 1720, which in FIG. 17 may include a high signal-to-noise microphone positioned to capture the voice of a wearer of the first earbud 1702. In some implementations, the first earbud 1702 includes one or more additional microphones, such as an array of microphones configured to detect ambient sounds and spatially distributed to support beamforming, an “inner” microphone proximate to the wearer's ear canal (e.g., to assist with active noise cancelling), and a self-speech microphone, such as a bone conduction microphone configured to convert sound vibrations of the wearer's ear bone or skull into an audio signal, etc. The second earbud 1704 can be configured in a substantially similar manner as the first earbud 1702.

In FIG. 17, components of the system 100 of FIG. 1, including the decode system 140 and the channel interface circuitry 150, are integrated into one or both of the earbuds 1706. In a particular example, the channel interface circuitry 150 is operable to receive a signal transmitted to one or both of the earbuds 1706 and to obtain, based on the signal, first bits representing first encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example, signals based on the decoded output can be provided to the speaker 120 for presentation to a user.

FIG. 18 is an implementation 1800 in which the device 102 includes a wireless speaker and voice activated device 1802. The wireless speaker and voice activated device 1802 can have wireless network connectivity and is configured to execute an assistant operation. The wireless speaker and voice activated device 1802 of FIG. 18 includes components of the system 100 of FIG. 1, including the speaker 120, the decode system 140, and the channel interface circuitry 150. Additionally, the wireless speaker and voice activated device 1802 includes a microphone 1804. In a particular example, the channel interface circuitry 150 is operable to receive a signal transmitted to the wireless speaker and voice activated device 1802 and to obtain, based on the signal, first bits representing first encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example, signals based on the decoded output can be provided to the speaker 120 for presentation to a user.

FIG. 19 depicts an implementation 1900 in which the device 102 is integrated into or includes a portable electronic device that corresponds to a camera 1902. In FIG. 19, the camera 1902 includes a microphone 1904 and the speaker 120. Additionally, components of the system 100 of FIG. 1, including the decode system 140 and the channel interface circuitry 150, may be integrated into the camera 1902. In a particular example, the channel interface circuitry 150 is operable to receive a signal transmitted to the camera 1902 and to obtain, based on the signal, first bits representing first encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example, signals based on the decoded output can be provided to the speaker 120, to a viewscreen (disposed, for example, on a backside of the camera 1902), or both, for presentation to a user,

FIG. 20 depicts an implementation 2000 in which the device 102 includes a portable electronic device that corresponds to an extended reality headset 2002 (e.g., a virtual reality headset, a mixed reality headset, an augmented reality headset, or a combination thereof). The extended reality headset 2002 includes a microphone 2004 and the speaker 120. In a particular aspect, the display 110 is positioned in front of the user's eyes to enable display of augmented reality, mixed reality, or virtual reality images or scenes to the user while the extended reality headset 2002 is worn. In a particular example, the display 110 is configured to display a notification indicating user speech detected in an audio signal from the microphone 2004. In a particular implementation, components of the system 100 of FIG. 1, including the decode system 140 and the channel interface circuitry 150, are integrated in the extended reality headset 2002. In a particular example, the channel interface circuitry 150 is operable to receive a signal transmitted to the extended reality headset 2002 and to obtain, based on the signal, first bits representing First encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example, signals based on the decoded output can be provided to the display 110, to the speaker 120, or both, for presentation to a user.

FIG. 21 depicts an implementation 2100 in which the device 102 corresponds to, or is integrated within, a vehicle 2102, illustrated as a manned or unmanned aerial device (e.g., a package delivery drone). The vehicle 2102 includes a microphone 2104 and the speaker 120. The vehicle 2102 may also include one or more cameras 2106. In a particular implementation, components of the system 100 of FIG. 1, including the decode system 140 and the channel interface circuitry 150, are also integrated in the vehicle 2102. In a particular example, the channel interface circuitry 150 is operable to receive a signal transmitted to the vehicle 2102 and to obtain, based on the signal, first bits representing first encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example, signals based on the decoded output can be provided to the speaker 120 for presentation to a user.

FIG. 22 depicts another implementation 2200 in which the device 102 corresponds to, or is integrated within, a vehicle 2202, illustrated as a car. The vehicle 2202 includes components of the system 100 of FIG. 1, including the decode system 140 and the channel interface circuitry 150. The vehicle 2202 also includes one or more microphones 2204, the speaker 120, and the display 110. The microphone(s)2204 are positioned to capture utterances of an operator of the vehicle 2202, a passenger of the vehicle 2202, or both. In a particular example, the channel interface circuitry 150 is operable to receive a signal transmitted to the vehicle 2202 and to obtain, based on the signal, first bits representing first encoded time-series data and a first indicator of reliability of the first bits. In this example, the decode system 140 is operable to process an input, using one or more trained models, to generate decoded output. The input is based at least in part on the first bits and the first indicator, and the decoded output represents decoded time-series data. In this example, signals based on the decoded output can be provided to the display 110, to the speaker 120, or both, for presentation to a user.

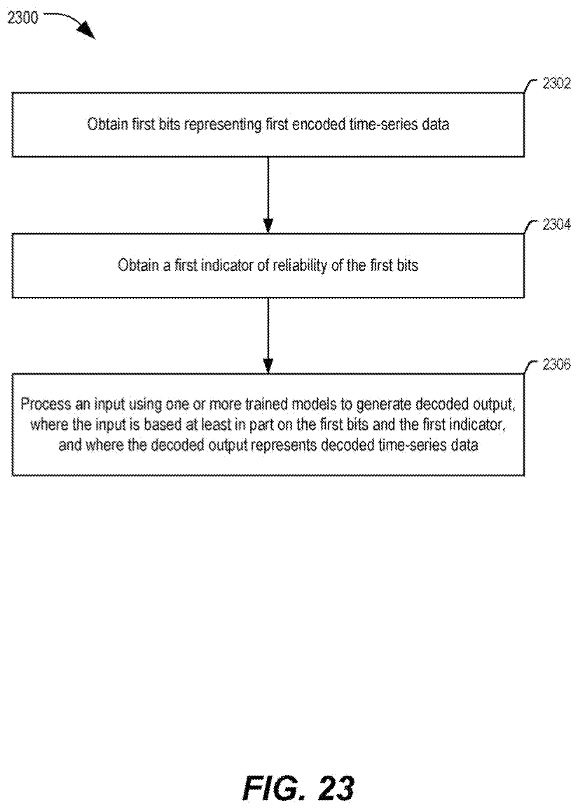

Referring to FIG. 23, a particular implementation of a method 2300 of decoding encoded data based on data reliability is shown. In a particular aspect, one or more operations of the method 2300 are performed by at least one of the channel interface circuitry 150, the decode system 140, the processor(s) 190, the device 102, the system 100 of FIG. 1, or a combination thereof.

The method 2300 includes, at block 2302, obtaining first bits representing first encoded time-series data. For example, the channel interface circuitry 150 of FIG. 1 may receive, via a modulated signal (e.g., the signal 135), one or more first symbols. In this example, the EDC 152 performs one or more error detection operations, one or more error correction operations, or both, to determine the first bits (e.g., the bits 181) based on the one or more first symbols.

The method 2300 also includes, at block 2304, obtaining a first indicator of reliability of the first bits. The first indicator of reliability indicates whether the first bits are associated with at least one bit error. For example, the EDC 152 determines the reliability indicator 183 associated with the bits 181. The first indicator of reliability may include, for example, a quality metric associated with the first bits, such as an estimated signal-to-noise ratio, an average LLR absolute value, an estimated BER, an estimated symbol error rate, or a combination thereof.

The method 2300 also includes, at block 2306, processing an input using one or more trained models to generate decoded output, where the input is based at least in part on the first bits and the first indicator, and the decoded output represents decoded time-series data. For example, the decode system 140 provides the input 185 to the trained model 192 to generate the decoded output 191. In this example, the input 185 is based on the bits 181 and the reliability indicator 183, and the decoded output 191 represents a decoded version of the time-series data 171. To illustrate, the time-series data 171 includes audio data, video data, or both, which is encoded to generate the encoded time-series data 173, and the decoded output 191 represents the audio data 126, the video data 116, or other media data 128. In a particular implementation, the trained model 192 includes the decoder neural network 428 of any of FIGS. 4-9.

In some implementations, in addition to determining the bits 181 and the reliability indicator 183, the EDC 152 also determines error statistics associated with the bits 181. In such implementations, the input 185 to the trained model 192 may also include the error statistics 275 of FIG. 2. To illustrate, the input 185 may be further based on error statistics 275 associated with one or more bits preceding the first bits in the first encoded time-series data.

In some implementations, the input includes values of a vector (e.g., a latent vector) where the values of the vector are determined based on the bits. For example, the method 2300 may include determining a first probability distribution indicating probabilities corresponding to a plurality of codebook values and estimating the values of a vector based on the first probability distribution as described with reference to FIG. or FIG. 11. In this example, the estimated values of the vector correspond to a first expected codebook value associated with the bits 181.

In some implementations, the input also includes or is based on additional information. For example, the input 185 may include a previous state (e.g., a previous hidden state) of at least one of the one or more trained models, a previous input to at least one of the one or more trained models, a previous output of at least one of the one or more trained models, a next input to at least one of the one or more trained models (e.g., the subsequent bits 271), a next indicator (e.g., the subsequent reliability indicator 273), or a combination thereof, as described with reference to FIG. 2.

In some implementations, the method 2300 includes receiving one or more first symbols representing the first bits via a modulated signal, and, subsequently, receiving one or more second symbols via the modulated signal. In some such implementations, the method 2300 also includes performing one or more error detection operations, one or more error correction operations, or both, based on the one or more second symbols to determine second bits. In such implementations, the method 2300 may also include determining second error statistics associated with the second bits and comparing the second error statistics to a threshold. The method 2300 may further include, in response to determining that the second error statistics fail to satisfy the threshold, processing a second input using the one or more trained models to generate a second decoded output, where the second input is based at least in part on copies of the first bits and a second indicator associated with the second bits.

In some implementations, the method 2300 includes determining one or more values of the input by obtaining a first quality metric associated with the first bits and estimating values of a vector based on the first quality metric, where the input includes the estimated values of the vector. The first quality metric may include, for example. per bit LLRs, in which case the method 23(0 may include determining a first statistic based on the per bit LLRs, where the first statistic includes a first distribution, a first expected value, a first variance, a first higher-order moment (e.g., skewness or kurtosis), or a combination thereof, and where the values of the vector are estimated based on the first statistic.

In some implementations, the method 2300 includes obtaining the first bits from channel interface circuitry and using a codebook lookup based on the first bits to determine values of a vector. In such implementations, the input includes the values of the vector.

In some implementations, the method 2300 includes receiving second bits representing second encoded time-series data and generating a second indicator of reliability of the second bits, where the input is further based on the second bits and the second indicator. For example, the systems 700, 800, or 900 of FIGS. 7-9 include multichannel decode system that are configured to receive the bits 181A via a first channel and to receive the bits 181B via a second channel. In these examples, the input to the decoder neural network 428 is based on the bits 181A, the reliability indicator 183A associated with the bits 181A, the bits 181B, and the reliability indicator 183B associated with the bits 181B. In these examples, the first encoded time-series data (e.g., the bits 410A) corresponds to a first portion of time-series data that is encoded at a first protection level, and the second encoded time-series data (e.g., the bits 410B) corresponds to a second portion of the time-series data that is encoded at a second protection level. The first protection level may offer greater protection (e.g., may correspond to a higher protection level) than the second protection level. In some such implementations, the first portion of time-series data is smaller (e.g., includes fewer bits) than the second portion of time-series data.

In some implementations, a decode system 140 includes more than one trained model 192, such as a first trained model and a second trained model (e.g., the first decoder neural network 428A and the second decoder neural network 428B of FIG. 9). In some such implementations, the method 2300 also includes processing, using the first trained model, a first input to generate an output of the first trained model, where the first input is based at least in part on the first bits and the first indicator, and processing, using the second trained model, a second input to generate an output of the second trained model, where the second input is based at least in part on the second bits and the second indicator. In such implementations, the method 2300 further includes combining the output of the first trained model and the output of the second trained model to generate the decoded output. In such implementations, the input 185 includes the first input and the second input. In some such implementations, the trained models also include a third trained model configured to combine the output of the first trained model and the output of the second trained model to generate the decoded output. For example, the third trained model may include or correspond to the combiner 904 of FIG. 9.

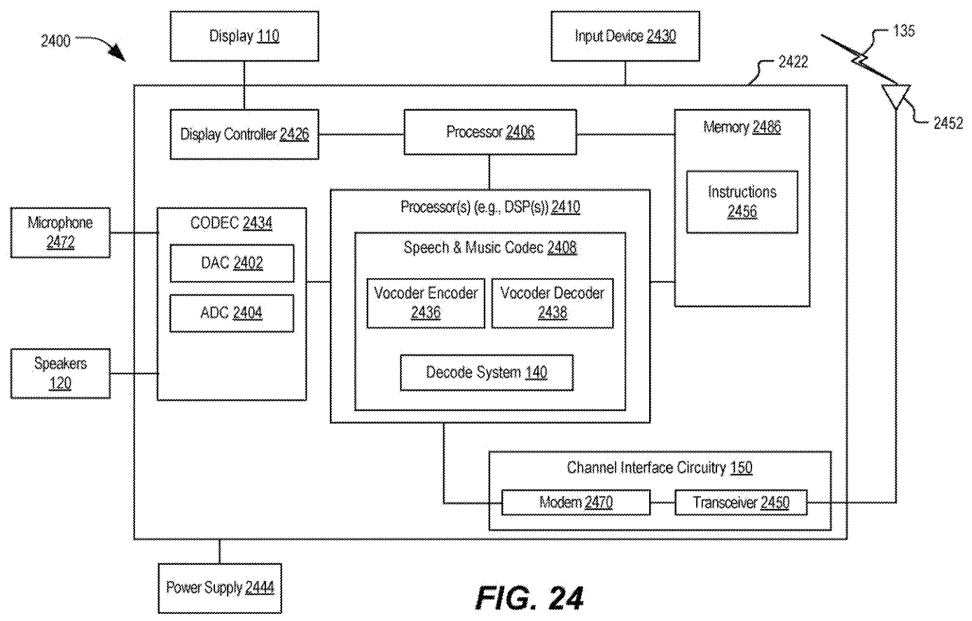

The method 2300 of FIG. 23 may be implemented by a field-programmable gate array (FPGA) device, an application-specific integrated circuit (ASIC, a processing twit such as a central processing unit (CPU), a DSP, a controller, another hardware device, firmware device, or any combination thereof. As an example, the method 23(0 of FIG. 23 may be performed by a processor that executes instructions, such as described with reference to FIG. 24.

Referring to FIG. 24, a block diagram of a particular illustrative implementation of a device is depicted and generally designated 2400. In various implementations, the device 2400 may have more or fewer components than illustrated in FIG. 24. In an illustrative implementation, the device 2400 may correspond to the device 102. In an illustrative implementation, the device 2400 may perform one or more operations described with reference to FIGS. 1-23.

In a particular implementation, the device 2400 includes a processor 2406 (e.g., a central processing unit (CPU)). The device 2400 may include one or more additional processors 2410 (e.g., one or more DSPs). In a particular aspect, the processor(s) 190 of FIG. 1 correspond to the processor 2406, the processors 2410, or a combination thereof. The processors 2410 may include a speech and music coder-decoder (CODEC) 2408 that includes a voice coder (“vocoder”) encoder 2436, a vocoder decoder 2438, the decode system 140, or a combination thereof.

The device 2400 may include a memory 2486 and a CODEC 2434. The memory 2486 may include instructions 2456 that am executable by the processor(s) 2410 (or the processor 2406) to implement the functionality described with reference to the decode system 140.

In FIG. 24, the device 2400 includes the channel interface circuitry 150, which includes a modem 2470 coupled, via a transceiver 2450, to an antenna 2452. The modem 2470, the transceiver 2450, and the antenna 2452 may be operable to receive an input media stream, to transmit an output media stream, or both. For example, the device 2400 may receive the signal 135 which is modulated to represent symbols corresponding to bits representing the encoded time-series data 173 of FIG. 1. In this example, the channel interface circuitry 150 is configured to determine bits 181 represented by the symbols, to detect and/or correct errors in the bits 181, and to generate the reliability indicator 183 associated with the bits 181.

The device 2400 may include the display 110 coupled to a display controller 2426. The speaker 120 and a microphone 2472 may be coupled to the CODEC 2434. The CODEC 2434 may include a digital-to-analog converter (DAC) 2402, an analog-to-digital converter (ADC) 2404, or both. In a particular implementation, the CODEC 2434 may receive analog signals from the microphone 2472, convert the analog signals to digital signals using the analog-to-digital converter 2404, and provide the digital signals to the speech and music codec 2408. The speech and music codec 2408 may process the digital signals. In a particular implementation, the speech and music codec 2408 may provide digital signals to the CODEC 2434. The CODEC 2434 may convert the digital signals to analog signals using the digital-to-analog converter 2402 and may provide the analog signals to the speaker 120.

In a particular implementation, the device 2400 may be included in a system-in-package or system-on-chip device 2422. In a particular implementation, the memory 2486, the processor 2406, the processors 2410, the display controller 2426, the CODEC 2434, and the modem 2470 (and optionally other components of the channel interface circuitry 150) are included in the system-in-package or system-on-chip device 2422. In a particular implementation, an input device 2430 and a power supply 2444 are coupled to the system-in-package or the system-on-chip device 2422. Moreover, in a particular implementation, as illustrated in FIG. 24, the display 110, the input device 2430, the speaker 120, the microphone 2472, the antenna 2452, and the power supply 2444 are external to the system-in-package or the system-on-chip device 2422. In a particular implementation, each of the display 110, the input device 2430, the speaker 120, the microphone 2472, the antenna 2452, and the power supply 2444 may be coupled to a component of the system-in-package or the system-on-chip device 2422, such as an interface or a controller.

The device 2400 may include a smart speaker, a speaker bar, a mobile communication device, a smart phone, a cellular phone, a laptop computer, a computer, a tablet, a personal digital assistant, a display device, a television, a gaming console, a music player, a radio, a digital video player, a digital video disc (DVD) player, a tuner, a camera, a navigation device, a vehicle, a headset, an augmented reality headset, a mixed reality headset, a virtual reality headset, an aerial vehicle, a home automation system, a voice-activated device, a wireless speaker and voice activated device, a portable electronic device, a car, a computing device, a communication device, an internet-of-things (IoT) device, a virtual reality (VR) device, a base station, a mobile device, or any combination thereof.

In conjunction with the described implementations, an apparatus includes means for obtaining first bits representing first encoded time-series data. For example, the means for obtaining first bits representing first encoded time-series data can correspond to the channel interface circuitry 150, the EDC 152, the decode system 140, the trained model 192, the processor(s) 190, the de-packetizer 426, the processor 2406, the processor(s) 2410, the transceiver 2450, the modem 2470, one or more other circuits or components configured to obtain bits representing encoded time-series data, or any combination thereof.

In conjunction with the described implementations, the apparatus also includes means for obtaining a first indicator of reliability of the first bits. For example, the means for obtaining a first indicator of reliability of the first bits can correspond to the channel interface circuitry 150, the EDC 152, the reliability indicator generator 154, the decode system 140, the trained model 192, the processor(s) 190, the de-packetizer 426, the processor 2406, the processor(s) 2410, one or more other circuits or components configured to obtain an indicator of reliability of bits, or any combination thereof.

In conjunction with the described implementations, the apparatus also includes means for processing an input using one or more trained models to generate decoded output, where the input is based at least in part on the first bits and the first indicator, and the decoded output represents decoded time-series data. For example, the means for processing the input can correspond to the decode system 140, the trained model 192, the decoder neural network 428, the combiner 904, the processor(s) 190, the processor 2406, the processor(s) 2410, one or more other circuits or components configured to process input to generate decoded output, or any combination thereof.

In some implementations, a non-transitory computer-readable medium (e.g., a computer-readable storage device, such as the memory 2486) includes instructions (e.g., the instructions 2456) that, when executed by one or more processors (e.g., the one or more processors 190, the one or more processors 2410 or the processor 2406), cause the one or more processors to obtain first bits representing first encoded time-series data.

The instructions are further executable by the one or more processors to obtain a first indicator of reliability of the first bits. The instructions are also executable by the one or more processors to process an input using one or more trained models to generate decoded output, where the input is based at least in part on the first bits and the first indicator, and where the decoded output represents decoded time-series data.

### Particular Aspects of the Disclosure are Described Below in Sets of Interrelated Examples

According to Example 1, a device includes one or more processors configured to: obtain first bits representing first encoded time-series data; obtain a first indicator of reliability of the first bits; and process an input using one or more trained models to generate decoded output, wherein the input is based at least in part on the first bits and the first indicator, and wherein the decoded output represents decoded time-series data.

Example 2 includes the device of Example 1, wherein the one or more trained models include a decoder neural network.

Example 3 includes the device of Example l or Example 2, wherein the first encoded time-series data includes audio data, video data, or both.

Example 4 includes the device of any of Examples 1-3, wherein the first indicator of reliability indicates whether the first bits are associated with at least one bit error.

Example 5 includes the device of any of Examples 1-4, further including channel interface circuitry configured to: receive, via a modulated signal, one or more first symbols; and perform, based on the one or more first symbols, one or more error detection operations, one or more error correction operations, or both, to determine the first bits and error statistics associated with the first bits.

Example 6 includes the device of Example 5, wherein the channel interface circuitry is further configured to, after receiving the one or more first symbols: receive, via the modulated signal, one or more second symbols; perform, based on the one or more second symbols, one or more error detection operations, one or more error correction operations, or both, to determine second bits and second error statistics associated with the second bits; compare the second error statistics to a threshold; and in response to determining that the second error statistics fail to satisfy the threshold, process a second input using the one or more trained models to generate a second decoded output, wherein the second input is based at least in part on copies of the first bits and a second indicator associated with the second bits.

Example 7 includes the device of any of Examples 1-6, wherein the input is further based on an error statistic associated with one or more bits preceding the first bits in the first encoded time-series data.

Example 8 includes the device of any of Examples 1-7, wherein the first indicator of reliability includes a first quality metric associated with the first bits, and wherein the first quality metric indicates a first estimated signal-to-noise ratio, a first LLR absolute value, a first estimated BER, a first estimated symbol error rate, or a combination thereof.

Example 9 includes the device of any of Examples 1-8, wherein the one or more processors are configured to: obtain a first quality metric associated with the first bits; and estimate values of a vector based on the first quality metric, wherein the input includes the estimated values of the vector.

Example 10 includes the device of Example 9, wherein the first quality metric includes per bit LLRs.

Example 11 includes the device of Example 10, wherein the one or more processors are configured to: determine a first statistic based on the per bit LLRs, wherein the first statistic includes a first distribution, a first expected value, a first variance, or a combination thereof, and wherein the values of the vector are estimated based on the first statistic.

Example 12 includes the device of any of Examples 1-11, wherein the one or more processors are configured to: determine a first probability distribution indicating probabilities corresponding to a plurality of codebook values and estimate values of a vector based on the first probability distribution, wherein the estimated values of the vector correspond to a first expected codebook value, and wherein the input includes the first expected codebook value.

Example 13 includes the device of any of Examples 1-12, wherein the input includes a previous state of at least one of the one or more trained models, a previous input to at least one of the one or more trained models, a previous output of at least one of the one or more trained models, a next input to at least one of the one or more trained models, a next indicator, or a combination thereof, to generate the decoded output.

Example 14 includes the device of any of Examples 1-13, wherein the one or more processors are configured to: obtain the first bits from channel interface circuitry; and use a codebook lookup based on the first bits to determine values of a vector, wherein the input includes the values of the vector.

Example 15 includes the device of any of Examples 1-14, wherein the one or more processors am configured to: receive second bits representing second encoded time-series data, generate a second indicator of reliability of the second bits, wherein the input is further based on the second bits and the second indicator.

Example 16 includes the device of Example 15, wherein the first encoded time-series data corresponds to a first portion of time-series data that is encoded at a first protection level, and wherein the second encoded time-series data corresponds to a second portion of the time-series data that is encoded at a second protection level.

Example 17 includes the device of Example 16, wherein the first protection level corresponds to higher protection than the second protection level, and wherein the first portion of time-series data is smaller than the second portion of time-series data.

Example 18 includes the device of any of Examples 15-17, wherein the second indicator of reliability includes a second quality metric associated with the second bits, and wherein the second quality metric indicates a second estimated signal-to-noise ratio, a second LLR absolute value, a second estimated BER, a second estimated symbol error rate, or a combination thereof.

Example 19 includes the device of any of Examples 1-18, wherein the one or more processors are configured to: obtain a second quality metric associated with the second bits; and estimate values of a vector based on the second quality metric, wherein the input includes the values of the vector.

Example 20 includes the device of Example 19, wherein the second quality metric includes per bit LLRs.

Example 21 includes the device of Example 20, wherein the one or more processors are configured to: determine a second statistic based on the per bit LLRs, wherein the second statistic includes a second distribution, a second expected value, a second variance, or a combination thereof, and wherein the values of the vector are estimated based on the second statistic.

Example 22 includes the device of any of Examples 15-21, wherein the one or more processors are configured to: determine a second probability distribution indicating probabilities corresponding to a plurality of codebook values and estimate values of a vector based on the second probability distribution, wherein the input includes a second expected codebook value.

Example 23 includes the device of any of Examples 15-22, wherein the one or more trained models include at least a first trained model and a second trained model, and wherein the one or more processors are configured to: process, using the first trained model, a first input to generate an output of the first trained model, wherein the first input is based at least in part on the first bits and the first indicator; process, using the second trained model, a second input to generate an output of the second trained model, wherein the second input is based at least in part on the second bits and the second indicator; and combine the output of the first trained model and the output of the second trained model to generate the decoded output, wherein the input includes the first input and the second input.

Example 24 includes the device of Example 23, wherein the one or more trained models further include a third trained model configured to combine the output of the first trained model and the output of the second trained model to generate the decoded output.

According to Example 25, a method includes obtaining, by one or more processors, first bits representing first encoded time-series data; obtaining, by the one or more processors, a first indicator of reliability of the first bits; and processing, by the one or more processors, an input using one or more trained models to generate decoded output, wherein the input is based at least in part on the first bits and the first indicator, and wherein the decoded output represents decoded time-series data.

Example 26 includes the method of Example 25, wherein the one or more trained models include a decoder neural network.

Example 27 includes the method of Example 25 or Example 26, wherein the first encoded time-series data includes audio data, video data, or both.

Example 28 includes the method of any of Examples 25-27, wherein the first indicator of reliability indicates whether the first bits are associated with at least one bit error.

Example 29 includes the method of any of Examples 25-28, further including: receiving, via a modulated signal, one or more first symbols; and performing, based on the one or more first symbols, one or more error detection operations, one or more error correction operations, or both, to determine the first bits and error statistics associated with the first bits.

Example 30 includes the method of Example 29, further including, after receiving the one or more first symbols: receiving, via the modulated signal, one or more second symbols; performing, based on the one or more second symbols, one or more error detection operations, one or more error correction operations, or both, to determine second bits and second error statistics associated with the second bits; comparing the second error statistics to a threshold; and in response to determining that the second error statistics fail to satisfy the threshold, processing a second input using the one or more trained models to generate a second decoded output, wherein the second input is based at least in part on copies of the first bits and a second indicator associated with the second bits.

Example 31 includes the method of any of Examples 25-30, wherein the input is further based on an error statistic associated with one or more bits preceding the first bits in the first encoded time-series data.

Example 32 includes the method of any of Examples 25-31, wherein the first indicator of reliability includes a first quality metric associated with the first bits, and wherein the first quality metric indicates a first estimated signal-to-noise ratio, a first LLR absolute value, a first estimated BER, a first estimated symbol error rate, or a combination thereof.

Example 33 includes the method of any of Examples 25-32, further including: obtaining a first quality metric associated with the first bits; and estimating values of a vector based on the first quality metric, wherein the input includes the estimated values of the vector.

Example 34 includes the method of Example 33, wherein the first quality metric includes per bit LLRs.

Example 35 includes the method of Example 34, further including: determining a first statistic based on the per bit LLRs, wherein the first statistic includes a first distribution, a first expected value, a first variance, or a combination thereof, and wherein the values of the vector are estimated based on the first statistic.

Example 36 includes the method of any of Examples 25-35, further including: determining a first probability distribution indicating probabilities corresponding to a plurality of codebook values and estimating values of a vector based on the first probability distribution, wherein the estimated values of the vector correspond to a first expected codebook value, and wherein the input includes the first expected codebook value.

Example 37 includes the method of any of Examples 25-36, wherein the input includes a previous state of at least one of the one or more trained models, a previous input to at least one of the one or more trained models, a previous output of at least one of the one or more trained models, a next input to at least one of the one or more trained models, a next indicator, or a combination thereof, to generate the decoded output.

Example 38 includes the method of any of Examples 25-37, further including: obtaining the first bits from channel interface circuitry; and using a codebook lookup based on the first bits to determine values of a vector, wherein the input includes the values of the vector.

Example 39 includes the method of any of Examples 25-38, further including: receiving second bits representing second encoded time-series data, generating a second indicator of reliability of the second bits, wherein the input is further based on the second bits and the second indicator.

Example 40 includes the method of Example 39, wherein the first encoded time-series data corresponds to a first portion of time-series data that is encoded at a first protection level, and wherein the second encoded time-series data corresponds to a second portion of the time-series data that is encoded at a second protection level.

Example 41 includes the method of Example 40, wherein the first protection level corresponds to higher protection than the second protection level, and wherein the first portion of time-series data is smaller than the second portion of time-series data.

Example 42 includes the method of any of Examples 39-41, wherein the second indicator of reliability includes a second quality metric associated with the second hits, and wherein the second quality metric indicates a second estimated signal-to-noise ratio, a second LLR absolute value, a second estimated BER, a second estimated symbol error rate, or a combination thereof.

Example 43 includes the method of any of Examples 39-42, further including: obtaining a second quality metric associated with the second bits; and estimating values of a vector based on the second quality metric, wherein the input includes the values of the vector.

Example 44 includes the method of Example 43, wherein the second quality metric includes per bit LLRs.

Example 45 includes the method of Example 44, further including: determining a second statistic based on the per bit LLRs, wherein the second statistic includes a second distribution, a second expected value, a second variance, or a combination thereof, and wherein the values of the vector are estimated based on the second statistic.

Example 46 includes the method of any of Examples 39-45, further including: determining a second probability distribution indicating probabilities corresponding to a plurality of codebook values and estimating values of a vector based on the second probability distribution, wherein the input includes a second expected codebook value.

Example 47 includes the method of any of Examples 39-46, wherein the one or more trained models include at least a first trained model and a second trained model, and further including: processing, using the first trained model, a first input to generate an output of the first trained model, wherein the first input is based at least in part on the first bits and the first indicator; processing, using the second trained model, a second input to generate an output of the second trained model, wherein the second input is based at least in part on the second bits and the second indicator, and combining the output of the first trained model and the output of the second trained model to generate the decoded output, wherein the input includes the first input and the second input.

Example 48 includes the method of Example 47, wherein the one or more trained models further include a third trained model configured to combine the output of the first trained model and the output of the second trained model to generate the decoded output.

According to Example 49, a non-transitory computer-readable medium stores instructions executable by one or more processors to cause the one or more processors to obtain first bits representing first encoded time-series data; obtain a first indicator of reliability of the first bits; and process an input using one or more trained models to generate decoded output, wherein the input is based at least in part on the first bits and the first indicator, and wherein the decoded output represents decoded time-series data.

Example 50 includes the non-transitory computer-readable medium of Example 49, wherein the one or more trained models include a decoder neural network.

Example 51 includes the non-transitory computer-readable medium of Example 49 or Example 50, wherein the first encoded time-series data includes audio data, video data, or both.

Example 52 includes the non-transitory computer-readable medium of any of Examples 49-51, wherein the first indicator of reliability indicates whether the first bits are associated with at least one bit error.

Example 53 includes the non-transitory computer-readable medium of any of Examples 49-52, wherein the instructions are further executable to cause the one or more processors to: receive, via a modulated signal, one or more first symbols; and perform, based on the one or more first symbols, one or more error detection operations, one or more error correction operations, or both, to determine the first bits and error statistics associated with the first bits.

Example 54 includes the non-transitory computer-readable medium of Example 53, wherein the instructions are further executable to cause the one or more processors to, after receiving the one or more first symbols: receive, via the modulated signal, one or more second symbols: perform, based on the one or more second symbols, one or more error detection operations, one or more error correction operations, or both, to determine second bits and second error statistics associated with the second bits; compare the second error statistics to a threshold; and in response to determining that the second error statistics fail to satisfy the threshold, process a second input using the one or more trained models to generate a second decoded output, wherein the second input is based at least in part on copies of the first bits and a second indicator associated with the second bits.

Example 55 includes the non-transitory computer-readable medium of any of Examples 49-54, wherein the input is further based on an error statistic associated with one or more bits preceding the first bits in the first encoded time-series data.

Example 56 includes the non-transitory computer-readable medium of any of Examples 49-56, wherein the first indicator of reliability includes a first quality metric associated with the first bits, and wherein the first quality metric indicates a first estimated signal-to-noise ratio, a first LLR absolute value, a first estimated BER, a first estimated symbol error rate, or a combination thereof.

Example 57 includes the non-transitory computer-readable medium of any of Examples 49-56, wherein the instructions are further executable to cause the one or more processors to: obtain a first quality metric associated with the first bits; and estimate values of a vector based on the first quality metric, wherein the input includes the estimated values of the vector.

Example 58 includes the non-transitory computer-readable medium of Example 57, wherein the first quality metric includes per bit LLRs.

Example 59 includes the non-transitory computer-readable medium of Example 58, wherein the instructions am further executable to cause the one or more processors to: determine a first statistic based on the per bit LLRs, wherein the first statistic includes a first distribution, a first expected value, a first variance, or a combination thereof, and wherein the values of the vector am estimated based on the first statistic.

Example 60 includes the non-transitory computer-readable medium of any of Examples 49-59, wherein the instructions are further executable to cause the one or more processors to: determine a first probability distribution indicating probabilities corresponding to a plurality of codebook values, and estimate values of a vector based on the first probability distribution, wherein the estimated values of the vector correspond to a first expected codebook value, and wherein the input includes the first expected codebook value.

Example 61 includes the non-transitory computer-readable medium of any of Examples 49-60, wherein the input includes a previous state of at least one of the one or more trained models, a previous input to at least one of the one or more trained models, a previous output of at least one of the one or more trained models, a next input to at least one of the one or more trained models, a next indicator, or a combination thereof, to generate the decoded output.

Example 62 includes the non-transitory computer-readable medium of any of Examples 49-61, wherein the instructions are further executable to cause the one or more processors to: obtain the first bits from channel interface circuitry; and use a codebook lookup based on the first bits to determine values of a vector, wherein the input includes the values of the vector.

Example 63 includes the non-transitory computer-readable medium of any of Examples 49-62, wherein the instructions are further executable to cause the one or more processors to: receive second bits representing second encoded time-series data, generate a second indicator of reliability of the second bits, wherein the input is further based on the second bits and the second indicator.

Example 64 includes the non-transitory computer-readable medium of Example 63, wherein the first encoded time-series data corresponds to a first portion of time-series data that is encoded at a first protection level, and wherein the second encoded time-series data corresponds to a second portion of the time-series data that is encoded at a second protection level.

Example 65 includes the non-transitory computer-readable medium of Example 64, wherein the first protection level corresponds to higher protection than the second protection level, and wherein the first portion of time-series data is smaller than the second portion of time-series data.

Example 66 includes the non-transitory computer-readable medium of any of Examples 63-65, wherein the second indicator of reliability includes a second quality metric associated with the second bits, and wherein the second quality metric indicates a second estimated signal-to-noise ratio, a second LLR absolute value, a second estimated BER, a second estimated symbol error rate, or a combination thereof.

Example 67 includes the non-transitory computer-readable medium of any of Examples 63-66, wherein the instructions are further executable to cause the one or more processors to: obtain a second quality metric associated with the second bits; and estimate values of a vector based on the second quality metric, wherein the input includes the values of the vector.

Example 68 includes the non-transitory computer-readable medium of Example 67, wherein the second quality metric includes per bit LLRs.

Example 69 includes the non-transitory computer-readable medium of Example 68, wherein the instructions are further executable to cause the one or more processors to: determine a second statistic based on the per bit LLRs, wherein the second statistic includes a second distribution, a second expected value, a second variance, or a combination thereof, and wherein the values of the vector are estimated based on the second statistic.

Example 70 includes the non-transitory computer-readable medium of any of Examples 63-69, wherein the instructions are further executable to cause the one or more processors to: determine a second probability distribution indicating probabilities corresponding to a plurality of codebook values and estimate values of a vector based on the second probability distribution, wherein the input includes a second expected codebook value.

Example 71 includes the non-transitory computer-readable medium of any of Examples 63-70, wherein the one or more trained models include at least a first trained model and a second trained model, and wherein the instructions are further executable to cause the one or mom processors to: process, using the first trained model, a first input to generate an output of the first trained model, wherein the first input is based at least in part on the first bits and the first indicator; process, using the second trained model, a second input to generate an output of the second trained model, wherein the second input is based at least in part on the second bits and the second indicator; and combine the output of the first trained model and the output of the second trained model to generate the decoded output, wherein the input includes the first input and the second input.

Example 72 includes the non-transitory computer-readable medium of Example 71, wherein the one or more trained models further include a third trained model configured to combine the output of the first trained model and the output of the second trained model to generate the decoded output.

According to Example 73, an apparatus includes means for obtaining first bits representing first encoded time-series data; means for obtaining a first indicator of reliability of the first bits; and means for processing an input using one or more trained models to generate decoded output, wherein the input is based at least in part on the first bits and the first indicator, and wherein the decoded output represents decoded time-series data.

Example 74 includes the apparatus of Example 73, wherein the one or more trained models include a decoder neural network.

Example 75 includes the apparatus of Example 73 or Example 74, wherein the first encoded time-series data includes audio data, video data, or both.

Example 76 includes the apparatus of any of Examples 73-75, wherein the first indicator of reliability indicates whether the first bits are associated with at least one bit error.

Example 77 includes the apparatus of any of Examples 73-76, further including: means for receiving, via a modulated signal, one or more first symbols; and means for performing, based on the one or more first symbols, one or more error detection operations, one or more error correction operations, or both, to determine the first hits and error statistics associated with the first bits.

Example 78 includes the apparatus of Example 77, further including: means for receiving, via the modulated signal, one or more second symbols after receiving the one or more first symbols; means for performing, based on the one or more second symbols, one or more error detection operations, one or more error correction operations, or both, to determine second bits and second error statistics associated with the second bits; means for comparing the second error statistics to a threshold; and means for processing a second input using the one or more trained models to generate a second decoded output in response to determining that the second error statistics fail to satisfy the threshold, wherein the second input is based at least in part on copies of the first bits and a second indicator associated with the second bits.

Example 79 includes the apparatus of any of Examples 73-78 wherein the input is further based on an error statistic associated with one or more bits preceding the first bits in the first encoded time-series data.

Example 80 includes the apparatus of any of Examples 73-79, wherein the first indicator of reliability includes a first quality metric associated with the first bits, and wherein the first quality metric indicates a first estimated signal-to-noise ratio, a first LLR absolute value, a first estimated BER, a first estimated symbol error rate, or a combination thereof.

Example 81 includes the apparatus of any of Examples 73-80, further including: means for obtaining a first quality metric associated with the first bits; and means for estimating values of a vector based on the first quality metric, wherein the input includes the estimated values of the vector.

Example 82 includes the apparatus of Example 81, wherein the first quality metric includes per bit LLRs.

Example 83 includes the apparatus of Example 82, further including: means for determining a first statistic based on the per bit LLRs, wherein the first statistic includes a first distribution, a first expected value, a first variance, or a combination thereof, and wherein the values of the vector are estimated based on the first statistic.

Example 84 includes the apparatus of any of Examples 73-83, further including: means for determining a first probability distribution indicating probabilities corresponding to a plurality of codebook values and means for estimating values of a vector based on the first probability distribution, wherein the estimated values of the vector correspond to a first expected codebook value, and wherein the input includes the first expected codebook value.

Example 85 includes the apparatus of any of Examples 73-84, wherein the input includes a previous state of at least one of the one or more trained models, a previous input to at least one of the one or more trained models, a previous output of at least one of the one or more trained models, a next input to at least one of the one or more trained models, a next indicator, or a combination thereof, to generate the decoded output.

Example 86 includes the apparatus of any of Examples 73-85, further including: means for obtaining the first bits from channel interface circuitry; and means for using a codebook lookup based on the first bits to determine values of a vector, wherein the input includes the values of the vector.

Example 87 includes the apparatus of any of Examples 73-86, further including: means for receiving second bits representing second encoded time-series data, means for generating a second indicator of reliability of the second bits, wherein the input is further based on the second bits and the second indicator.

Example 88 includes the apparatus of Example 87, wherein the first encoded time-series data corresponds to a first portion of time-series data that is encoded at a first protection level, and wherein the second encoded time-series data corresponds to a second portion of the time-series data that is encoded at a second protection level.

Example 89 includes the apparatus of Example 88, wherein the first protection level corresponds to higher protection than the second protection level, and wherein the first portion of time-series data is smaller than the second portion of time-series data.

Example 90 includes the apparatus of any of Examples 87-89, wherein the second indicator of reliability includes a second quality metric associated with the second bits, and wherein the second quality metric indicates a second estimated signal-to-noise ratio, a second LLR absolute value, a second estimated BER, a second estimated symbol error rate, or a combination thereof.

Example 91 includes the apparatus of any of Examples 87-90, further including: means for obtaining a second quality metric associated with the second bits; and means for estimating values of a vector based on the second quality metric, wherein the input includes the values of the vector.

Example 92 includes the apparatus of Example 91, wherein the second quality metric includes per bit LLRs.

Example 93 includes the apparatus of Example 92, further including: means for determining a second statistic based on the per bit LLRs, wherein the second statistic includes a second distribution, a second expected value, a second variance, or a combination thereof, and wherein the values of the vector are estimated based on the second statistic.

Example 94 includes the apparatus of any of Examples 87-93, further including: means for determining a second probability distribution indicating probabilities corresponding to a plurality of codebook values and means for estimating values of a vector based on the second probability distribution, wherein the input includes a second expected codebook value.

Example 95 includes the apparatus of any of Examples 87-94, wherein the one or more trained models include at least a first trained model and a second trained model, and further including: means for processing, using the first trained model, a first input to generate an output of the first trained model, wherein the first input is based at least in part on the first bits and the first indicator, means for processing, using the second trained model, a second input to generate an output of the second trained model, wherein the second input is based at least in part on the second bits and the second indicator; and means for combining the output of the first trained model and the output of the second trained model to generate the decoded output, wherein the input includes the first input and the second input.

Example 96 includes the apparatus of Example 95, wherein the one or more trained models further include a third trained model configured to combine the output of the first trained model and the output of the second trained model to generate the decoded output.

Those of skill would further appreciate that the various illustrative logical blocks, configurations, modules, circuits, and algorithm steps described in connection with the implementations disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, such implementation decisions are not to be interpreted as causing a departure from the scope of the present disclosure.

The steps of a method or algorithm described in connection with the implementations disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor may read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed aspects is provided to enable a person skilled in the art to make or use the disclosed aspects. Various modifications to these aspects will be readily apparent to those skilled in the art, and the principles defined herein may be applied to other aspects without departing from the scope of the disclosure. Thus, the present disclosure is not intended to be limited to the aspects shown herein but is to be accorded the widest scope possible consistent with the principles and novel features as defined by the following claims.

1. A device comprising:
one or more processors configured to:
obtain first bits representing first encoded time-series data; obtain a first indicator of reliability of the first bits; and
process an input using one or more trained models to generate decoded output, wherein the input is based at least in part on the first bits and the first indicator, and wherein the decoded output represents decoded time-series data.

2. The device of claim 1, wherein the one or more trained models include a decoder neural network.

3. The device of claim 1, wherein the first encoded time-series data includes audio data, video data, or both.

4. The device of claim 1, wherein the first indicator of reliability indicates whether the first bits are associated with at least one bit error.

5. The device of claim 1, further comprising channel interface circuitry configured to:
receive, via a modulated signal, one or more first symbols; and
perform, based on the one or more first symbols, one or more error detection operations, one or more error correction operations, or both, to determine the first bits and error statistics associated with the first bits.

6. The device of claim 5, wherein the channel interface circuitry is further configured to, after receiving the one or more first symbols:
receive, via the modulated signal, one or more second symbols;
perform, based on the one or more second symbols, one or more error detection operations, one or more error correction operations, or both, to determine second bits and second error statistics associated with the second bits;
compare the second error statistics to a threshold; and
in response to determining that the second error statistics fail to satisfy the threshold, process a second input using the one or more trained models to generate a second decoded output, wherein the second input is based at least in part on copies of the first bits and a second indicator associated with the second bits.

7. The device of claim 1, wherein the input is further based on an error statistic associated with one or more bits preceding the first bits in the first encoded time-series data.

8. The device of claim 1, wherein the first indicator of reliability includes a first quality metric associated with the first bits, and wherein the first quality metric indicates a first estimated signal-to-noise ratio, a first average log likelihood ratio (LLR) absolute value, a first estimated bit error rate (BER), a first estimated symbol error rate, or a combination thereof.

9. The device of claim 1, wherein the one or more processors are configured to:
obtain a first quality metric associated with the first bits; and
estimate values of a vector based on the first quality metric, wherein the input includes the estimated values of the vector.

10. The device of claim 9, wherein the first quality metric includes per bit log likelihood ratios (LLRs).

11. The device of claim 10, wherein the one or more processors are configured to: determine a first statistic based on the per bit LLRs, wherein the first statistic includes a first distribution, a first expected value, a first variance, a first higher-order moment or a combination thereof, and wherein the values of the vector are estimated based on the first statistic.

12. The device of claim 1, wherein the one or more processors are configured to:
determine a first probability distribution indicating probabilities corresponding to a plurality of codebook values, and
estimate values of a vector based on the first probability distribution, wherein the estimated values of the vector correspond to a first expected codebook value, and wherein the input includes the first expected codebook value.

13. The device of claim 1, wherein the input includes a previous state of at least one of the one or more trained models, a previous input to at least one of the one or more trained models, a previous output of at least one of the one or more trained models, a next input to at least one of the one or more trained models, a next indicator, or a combination thereof, to generate the decoded output.

14. The device of claim 1, wherein the one or more processors are configured to:
obtain the first bits from channel interface circuitry; and
use a codebook lookup based on the first bits to determine values of a vector, wherein the input includes the values of the vector.

15. The device of claim 1, wherein the one or more processors are configured to:
receive second bits representing second encoded time-series data; and generate a second indicator of reliability of the second bits, wherein the input is further based on the second bits and the second indicator.

16. The device of claim 15, wherein the first encoded time-series data corresponds to a first portion of time-series data that is encoded at a first protection level, and wherein the second encoded time-series data corresponds to a second portion of the time-series data that is encoded at a second protection level.

17. The device of claim 16, wherein the first protection level corresponds to higher protection than the second protection level, and wherein the first portion of time-series data is smaller than the second portion of time-series data.

18. The device of claim 15, wherein the second indicator of reliability includes a second quality metric associated with the second bits, and wherein the second quality metric indicates a second estimated signal-to-noise ratio, a second average log likelihood ratio (LLR) absolute value, a second estimated bit error rate (BER), a second estimated symbol error rate, or a combination thereof.

19. The device of claim 15, wherein the one or more processors are configured to:
obtain a second quality metric associated with the second bits; and
estimate values of a vector based on the second quality metric, wherein the input includes the values of the vector.

20. The device of claim 19, wherein the second quality metric includes per bit log likelihood ratios (LLRs).

21-30: (canceled)
